(19) United States
(12) Patent Application Publication
(10) Pub. No.: US 2022/0336576 A1
(43) Pub. Date: Oct. 20, 2022

(54) SEMICONDUCTOR DEVICE AND MANUFACTURING METHOD THEREOF

(71) Applicant: TAIWAN SEMICONDUCTOR MANUFACTURING COMPANY, LTD., Hsinchu (TW)

(72) Inventors: Tsung-Chieh HSIAO, Shetou Township (TW); Hsiang-Ku SHEN, Hsinchu City (TW); Yuan-Yang HSIAO, Taipei (TW); Ying-Yao LAI, Taichung City (TW); Dian-Hau CHEN, Hsinchu (TW)

(21) Appl. No.: 17/488,277

(22) Filed: Sep. 28, 2021

Related U.S. Application Data
(60) Provisional application No. 63/175,882, filed on Apr. 16, 2021.

(51) Int. Cl. H01L 49/02; H01L 23/522; H01L 27/108; H01L 27/08; H01L 21/768

(52) U.S. Cl. CPC H01L 28/75; H01L 23/5223; H01L 27/10852; H01L 27/10808; H01L 27/0805; H01L 21/76877; H01L 21/76805

(57) ABSTRACT

A semiconductor device includes a metal-insulator-metal (MIM) capacitor. The MIM capacitor includes: electrodes including one or more first electrodes and one or more second electrodes; and one or more insulating layers disposed between adjacent electrodes. The MIM capacitor is disposed in an interlayer dielectric (ILD) layer disposed over a substrate. The one or more first electrodes are connected to a side wall of a first via electrode disposed in the ILD layer, and the one or more second electrodes are connected to a side wall of a second via electrode disposed in the ILD layer. In one or more of the foregoing or following embodiments, the one or more insulating layers include a high-k dielectric material.

### RELATED APPLICATIONS

This application claims the priority of U.S. Provisional Application No. 63/175,882 filed on Apr. 16, 2021, the entire contents of which application are incorporated herein by reference.

### BACKGROUND

A dynamic access memory (DRAM) is one of the important semiconductor devices in the semiconductor industry. The DRAM cell generally includes a capacitor formed by a metal-insulator-semiconductor (MIS) structure or a metal-insulator-metal (MIM) structure. As the dimensions of the DRAM cell decreases, metal resistivity of a memory cell capacitor increases, and leakage also drastically increases. Increased storage capacity of DRAM cell capacitors is continually required large while the dimensions of the cell area shrink. The scaling down problem of the metal and the oxide is becoming a serious obstacle to higher device density.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross sectional view of a semiconductor device including a DRAM cell in accordance with embodiments of the present disclosure. FIG. 1B shows a circuit diagram corresponding to FIG. 1A.

FIGS. 2, 3, 4, 5, 6 and 7 show cross sectional views of the various stages of a sequential manufacturing operation of a semiconductor device in accordance with embodiments of the present disclosure.

FIGS. 8A, 8B, 9A, 9B, 10A, 10B, 11A, 11B, 12A, 12B, 13A, 13B, 14A, 14B, 15A, 15B, 16A, 16B, 17A, 17B, 18A, 18B, 19A, 19B, 19C and 19D show views of the various stages of a sequential manufacturing operation of a MIM capacitor structure in accordance with embodiments of the present disclosure.

FIGS. 20A and 20B show a semiconductor device including a DRAM cell in accordance with embodiments of the present disclosure.

FIGS. 21A and 21B show a semiconductor device including a DRAM cell in accordance with embodiments of the present disclosure.

FIGS. 22A and 22B show a semiconductor device including a DRAM cell in accordance with embodiments of the present disclosure.

FIG. 23 shows a semiconductor device including a DRAM cell in accordance with embodiments of the present disclosure.

FIGS. 24 and 25 show cross sectional views of the various stages of a sequential manufacturing operation of a MIM capacitor structure in accordance with embodiments of the present disclosure.

FIG. 26 shows a semiconductor device including a DRAM cell in accordance with embodiments of the present disclosure.

FIGS. 27, 28, 29, 30, 31, 32, 33 and 34 show cross sectional views of the various stages of a sequential manufacturing operation of a MIM capacitor structure in accordance with embodiments of the present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity. In the accompanied drawings, some layers/features may be omitted for simplification.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of” Further, in the following fabrication process, there may be one or more additional operations in/between the described operations, and the order of operations may be changed.

In the present disclosure, a semiconductor device includes a volatile memory cell, such as a dynamic random access memory (DRAM) cell having a metal-insulator-metal (MIM) structure disposed over transistors. More specifically, the memory cell includes multiple layers of conductive material and multiple layers of insulating material, which are disposed in a trench formed in an interlayer dielectric (ILD) layer or an inter-metal dielectric (IMD) layer.

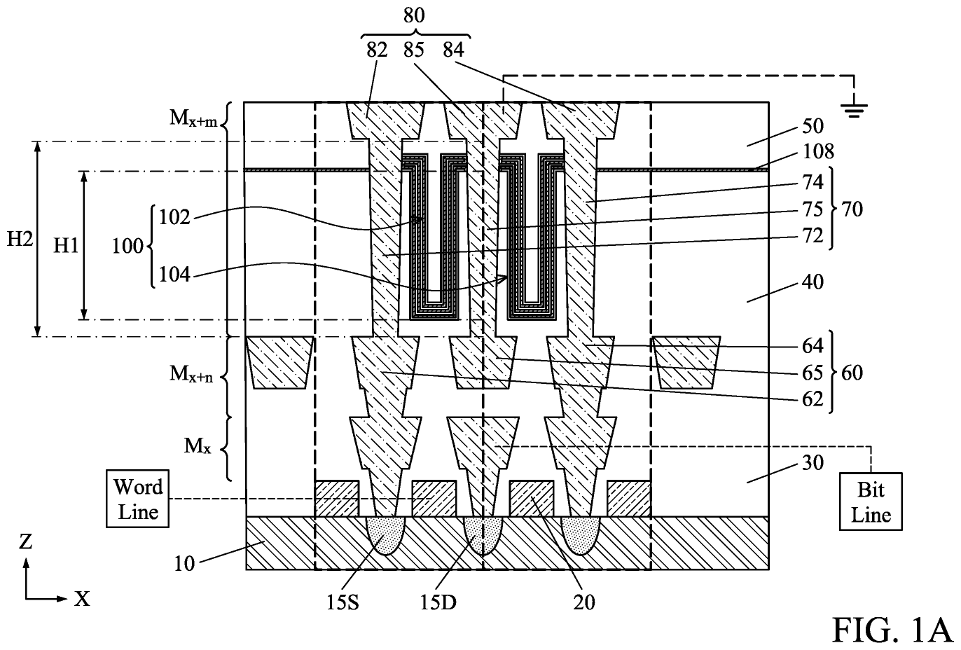

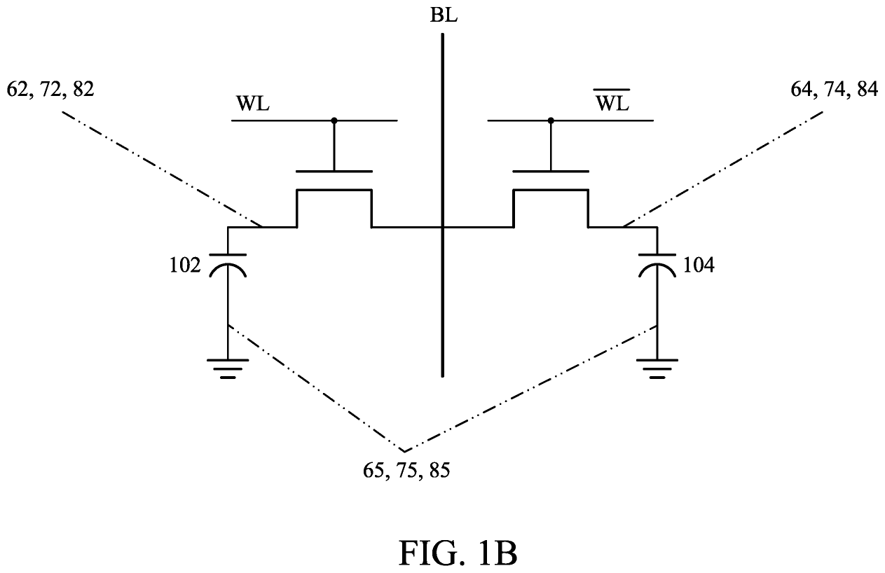

FIG. 1A is a cross sectional view of a semiconductor device including a DRAM in accordance with embodiments of the present disclosure. FIG. 1B shows a circuit diagram corresponding to FIG. 1A.

As shown in FIG. 1A, a semiconductor device includes MIM capacitors 100 including a first MIM capacitor 102 and a second MIM capacitor 104. The MIM capacitors 100 include two or more conductive layers and one or more insulating material layers disposed adjacent conductive layers. In some embodiments, the conductive layers include one or more data storage electrodes and one or more plate electrodes that are coupled to a fixed potential, such as the ground. As shown in FIG. 1A, the MIM capacitors 100 are disposed in trenches formed in an ILD or IMD layer 40.

In some embodiments, the MIM capacitors 100 are disposed over a semiconductor substrate 10. In some embodiments, the substrate 10 may be made of a suitable elemental semiconductor, such as silicon, diamond or germanium; a suitable alloy or compound semiconductor, such as Group-IV compound semiconductors (silicon germanium (SiGe), silicon carbide (SiC), silicon germanium carbide (SiGeC), GeSn, SiSn, SiGeSn), Group III-V compound semiconductors (e.g., gallium arsenide, indium gallium arsenide InGaAs, indium arsenide, indium phosphide, indium antimonide, gallium arsenic phosphide, or gallium indium phosphide), or the like. The substrate 10 includes isolation regions in some embodiments, such as shallow trench isolation (STI), defining active regions and separating one or more electronic elements from other electronic elements.

In some embodiments, transistors, such as field effect transistors (FETs), are disposed over the substrate. In some embodiments, the FET includes a gate electrode 20, a source 15S and a drain 15D. In the present disclosure, a source and a drain are interchangeably used and may have the same structure. In some embodiments, the FET is a planar FET, a fin FET (Fin FET) or a gate-all-around (GAA) FET.

In some embodiments, multiple wiring layers Mₓ are formed over the FETs, where x is 1, 2, 3, . . . , as shown in FIG. 1A. In some embodiments, when the wiring layers Mₓ include wiring patterns extending in the X direction, the wiring layers Mₓ₊₁ include wiring patterns extending in the Y direction. In other words, X-direction metal wiring patterns and Y-direction metal wiring patterns are alternately stacked. In some embodiments, x is up to 20. Each of the wiring layers includes an ILD or IMD layer, a metal layer and a via connected to the metal layer in some embodiments. In some embodiments, the wiring layer includes the via formed below the metal layer, and in other embodiments, the wiring layer is defined to include the via above the metal layer.

In some embodiments, the MIM capacitors 100 are formed between the metal wiring layer Mₓ₊ₙ and the metal wiring layer Mₓ₊ₙ₊ₘ, where n is a natural number and m is any of 1, 2, 3, 4 or 5. In some embodiments, the metal wiring layer Mₓ₊ₙ₊ₘ is formed with an ILD or IMD layer 50. In some embodiments, an insulating layer 108 made of the same material as the insulating material as the ILD layers if the MIM capacitors is disposed between the ILD layer 40 and ILD layer 50. As shown in FIG. 1A, an ILD layer 30 is formed below the ILD layer 40 in some embodiments.

As shown in FIG. 1A, the data storage electrodes of the MIM capacitors 102 and 104 are connected to a first via electrode 72 and a second via electrode 74, respectively, and the plate electrodes of the MIM capacitors 102 and 104 are commonly connected to a third via electrode 75. The first, second and third via electrodes may be collectively referred to as via electrodes 70. In some embodiments, the first, second and third via electrodes are connected to a first lower wiring pattern (pad) 62, a second lower wiring pattern (pad) 64 and a third lower wiring pattern (pad) 65, respectively, at the bottom thereof, and connected to a first upper wiring pattern (pad) 82, a second upper wiring pattern (pad) 84 and a third upper wiring pattern (pad) 85, respectively, at the top thereof. The first, second and third lower wiring patterns may be collectively referred to as Mₓ₊ₙ (or lower) wiring patterns 60, and the first, second and third upper wiring patterns may be collectively referred to as Mₓ₊ₙ₊ₘ (or upper) wiring patterns 80. Each of the first, second and third via electrodes has a single columnar shape and has no intermediate pad electrode in some embodiments.

In some embodiments, the data storage electrodes and the plate electrodes of the MIM capacitors 102 and 104 are connected to side walls of the respective via electrodes between Mₓ₊ₙ wiring patterns 60 and Mₓ₊ₙ₊ₘ wiring patterns 80, as shown in FIG. 1A. In some embodiments, the data storage electrodes and the plate electrodes of the MIM capacitors 102 and 104 fully surround the side walls of the respective via electrodes. In other embodiments, the data storage electrodes of the MIM capacitors 102 and 104 only partially surround the side walls of the respective via electrodes.

As shown in FIG. 1A, the data storage electrodes of the first MIM capacitor 102 are coupled to one of the sources 15S through the first via electrode 72, the first lower wiring pattern 62 and one or more metal wiring layers (each including a metal wiring pattern and a via), and the data storage electrodes of the second MIM capacitor 104 are coupled to another of the sources 15S through the second via electrode 74, the second lower wiring pattern 64, and one or more metal wiring layers. As shown in FIGS. 1A and 1B, the data storage electrodes are electrically coupled to the bit line when the respective transistors are turned on. The gate electrodes 20 of the transistors function as a word line WL and a complementary world line W̅L̅. In some embodiments, the plate electrodes of the first and second MIM capacitors are coupled to the fixed potential through the third via electrode 75 and one of or both of the third lower wiring pattern 65 and the third upper wiring pattern 85.

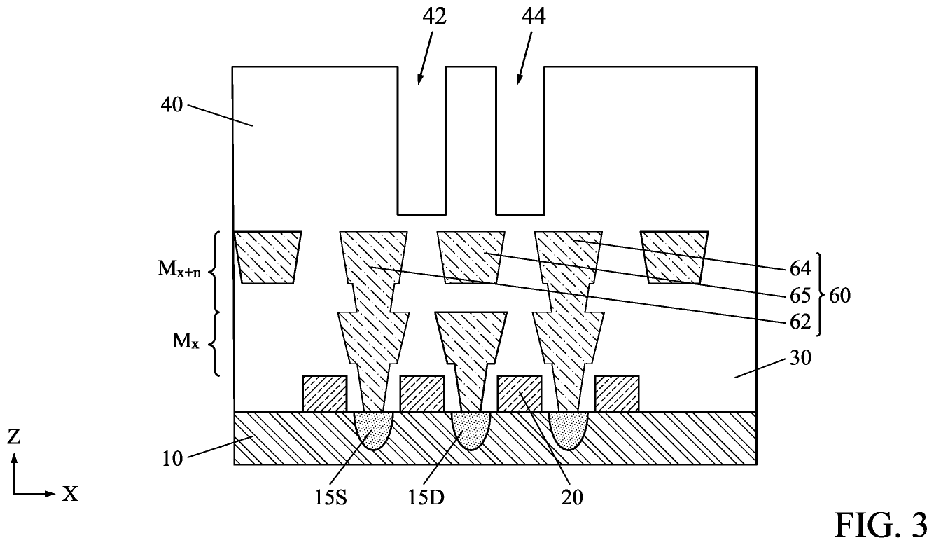

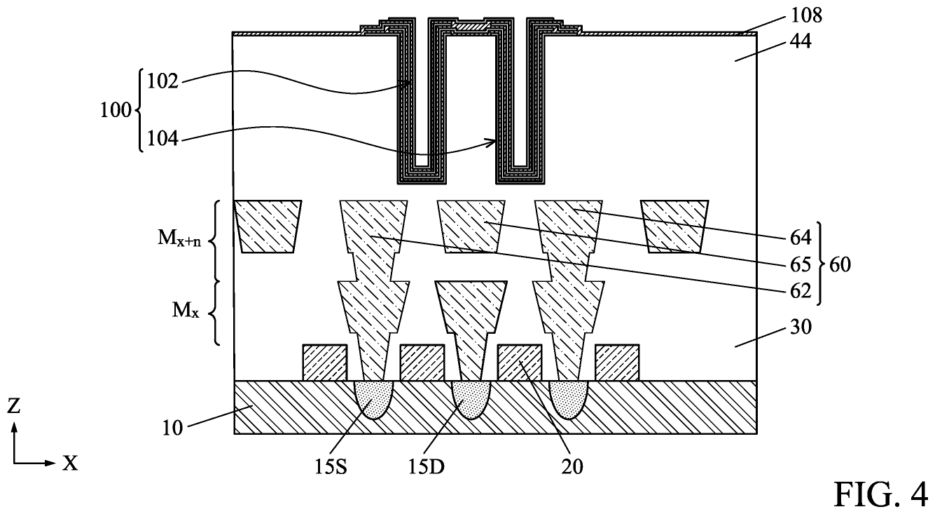

As shown in FIG. 1A, the first MIM capacitor 102 and the second MIM capacitor 104 are disposed in a trench formed in an interlayer dielectric layer respectively (see, FIGS. 3-4). In some embodiments, a depth H1 of the trench is about 50% to about 90% of a vertical distance H2 between the bottom of the wiring patterns 80 at the Mₓ₊ₙ₊ₘ wiring patterns and the top of the wiring patterns 60 at the Mₓ₊ₙ wiring patterns. In other embodiments, the depth H1 of the trench is about 60% to about 80% of the vertical distance H2, depending on the design and process requirements.

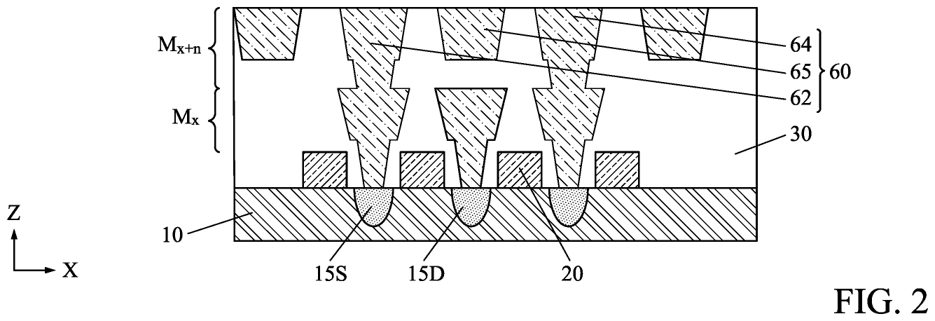

FIGS. 2-7 show cross sectional views of the various stages of a sequential manufacturing operation of a semiconductor device in accordance with embodiments of the present disclosure. It is understood that additional operations can be provided before, during, and after processes shown by FIGS. 2-7, and some of the operations described below can be replaced or eliminated, for additional embodiments of the method. The order of the operations/processes may be interchangeable.

As shown in FIG. 2, lower wiring patterns 60 including the first, second and third lower wiring patterns 62, 64 and 65 are formed over the FETs. In some embodiments, the lower wiring patterns 60 are formed be using a damascene technology, and include one or more layers of conductive material, such as Cu, Al, W, Co, Ti or Ta or an alloy thereof. The lower wiring patterns 60 are formed at the upper portion of a first ILD layer 30.

Then, as shown in FIG. 3, a second ILD layer 40 is formed over the first ILD layer 30 and the lower wiring patterns 60. In some embodiments, the first and second ILD layers 30 and 40 include one or more layers of silicon oxide, SiON, SiOCN, SiCN, SiOC, an organic material, a low-k dielectric material, or an extreme low-k dielectric material. Further, as shown in FIG. 3, a first trench 42 and a second trench 44 are formed in the second ILD layer 40 by using one or more lithography and etching operations. As shown in FIG. 3, no wiring pattern of the Mₓ₊ₙ wiring layer is exposed at the bottom of the trenches. In some embodiments, the first trench 42 is formed at the center between the first lower wiring pattern 62 and the third lower wiring pattern 65 and the second trench 44 is formed at the center between the second lower wiring pattern 64 and the third lower wiring pattern 65, in plan view. In some embodiments, the shape of the opening of the trench is circular, ellipse or square with rounded corners in plan view.

Then, as shown in FIG. 4, stacked layers of conductive material and insulating material are formed in the trenches and over the upper surface of the second ILD layer 40. The details of the operations to fabricate the stacked layers are explained later. In some embodiments, the upper surface of the second ILD layer 40 is fully covered by an insulating material layer 108.

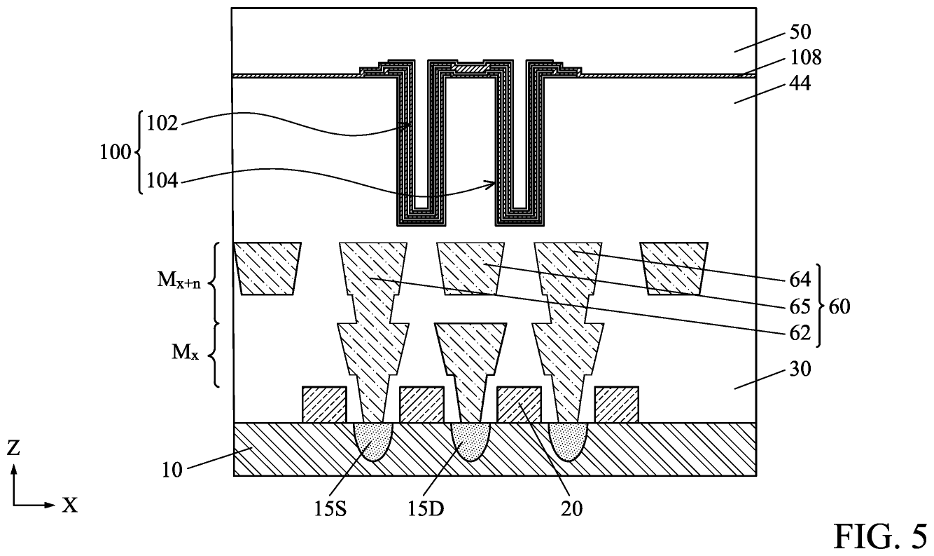

Next, as shown in FIG. 5, a third ILD layer 50 is formed over the insulating material layer 108. In some embodiments, the third ILD layer 50 includes one or more layers of silicon oxide, SiON, SiOCN, SiCN, SiOC, an organic material, a low-k dielectric material, or an extreme low-k dielectric material.

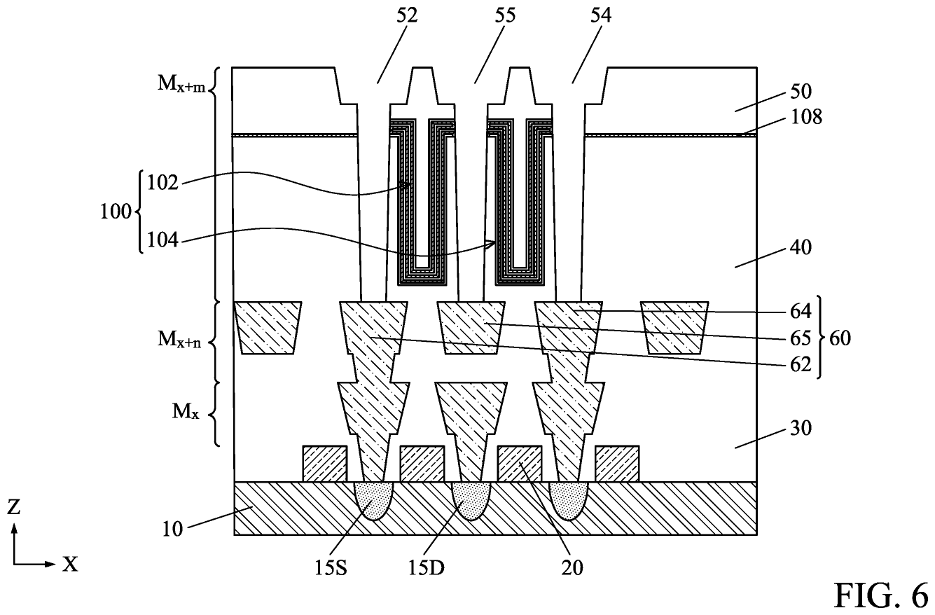

Then, as shown in FIG. 6, a first opening 52, a second opening 54 and a third opening 55 are formed in the third and second ILD layers. As shown in FIG. 6, the first, second and third lower wiring patterns 62, 64 and 65 are at least partially exposed at the bottoms of the first, second and third openings 52, 54 and 55, respectively. Further, one or more conductive layers in the stacked layers which are to be formed as the data storage electrodes of the MIM capacitors are exposed in the first and second openings 52 and 54, and one or more conductive layers in the stacked layers which are to be formed as the plate electrodes of the MIM capacitors are exposed in the third opening 55. In other words, the first and second openings 52 and 54 are formed to etch at least part of the conductive layers in the stacked layers which are to be formed as the data storage electrodes, and the third opening 55 is formed to etch at least part of the conductive layers in the stacked layers which are to be formed as the plate electrode. The one or more conductive layers in the stacked layers which are to be formed as the data storage electrodes of the MIM capacitors are not exposed in the third opening 55, and the one or more conductive layers in the stacked layers which are to be formed as the plate electrodes of the MIM capacitors are not exposed in the first and second openings 52 and 54. As shown in FIG. 6, the first, second and third openings include a via portion and a wiring portion formed over the via portion and having a greater area (width and/or length) than the via portion in plan view, respectively.

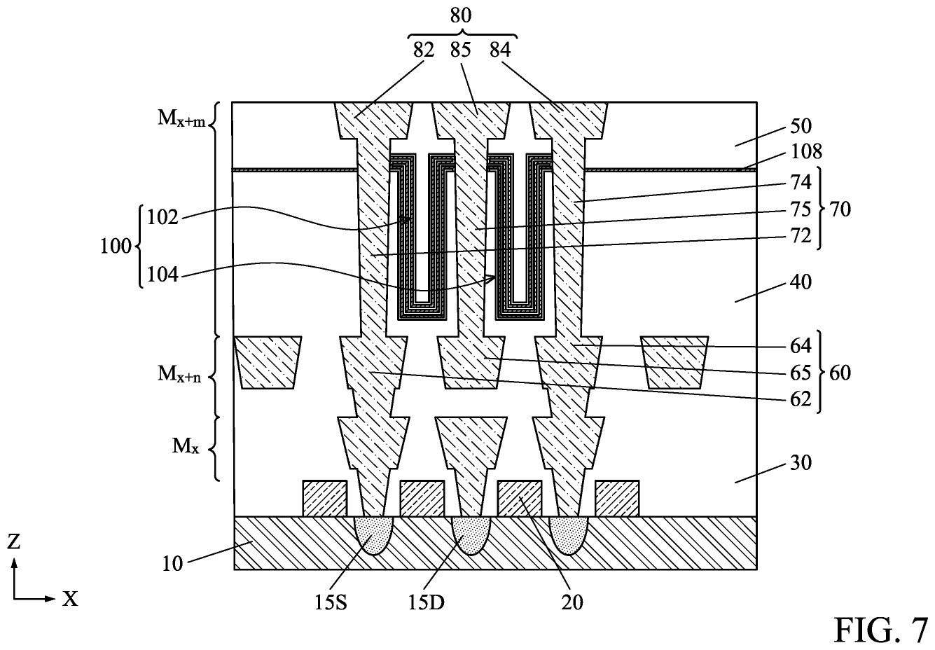

Subsequently, one or more conductive materials are formed to fill the first, second and third openings 52, 54 and 55 as shown in FIG. 7. In some embodiments, the conductive materials include one or more layers of Cu, Al, W, Co, Ti or Ta or an alloy thereof.

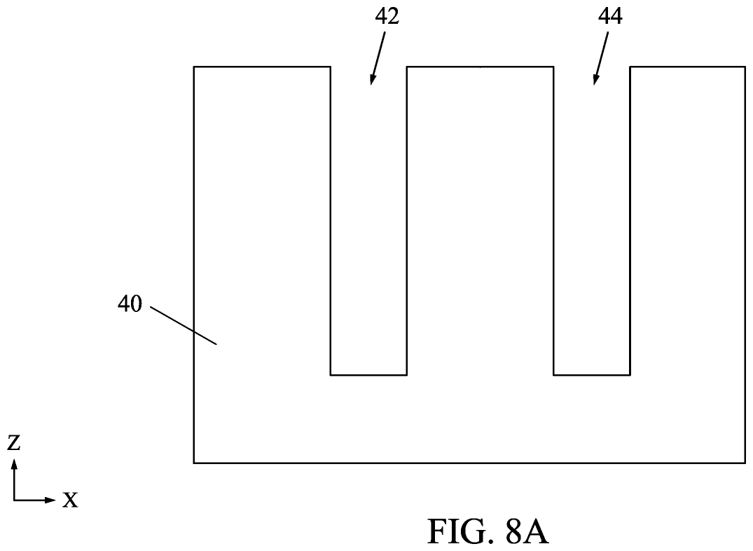

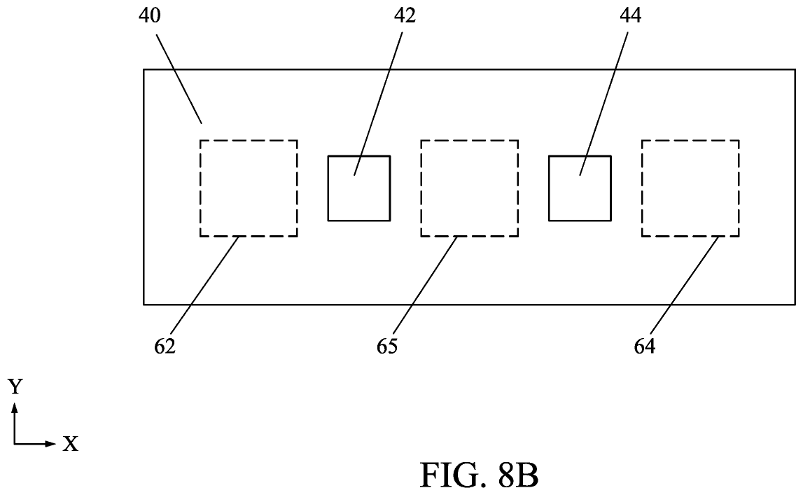

FIGS. 8A and 8B to 19A and 19B show views of the various stages of a sequential manufacturing operation of a MIM capacitor structure in accordance with embodiments of the present disclosure. It is understood that additional operations can be provided before, during, and after processes shown by FIGS. 8A and 8B to 19A and 19B, and some of the operations described below can be replaced or eliminated, for additional embodiments of the method. The order of the operations/processes may be interchangeable. In FIGS. 8A and 8B to 19A and 19B, the “A” figures are cross sectional views and the “B” figures are plan views, in which some of the features may be omitted or be transparent for simplicity.

FIGS. 8A and 8B correspond to the structure shown in FIG. 3. As shown in FIG. 8B, the trenches 42 and 44 are formed so as not to overlap the lower wiring layers 62, 64 and 65 of the Mₓ₊ₙ wiring layer in plan view (or projected view).

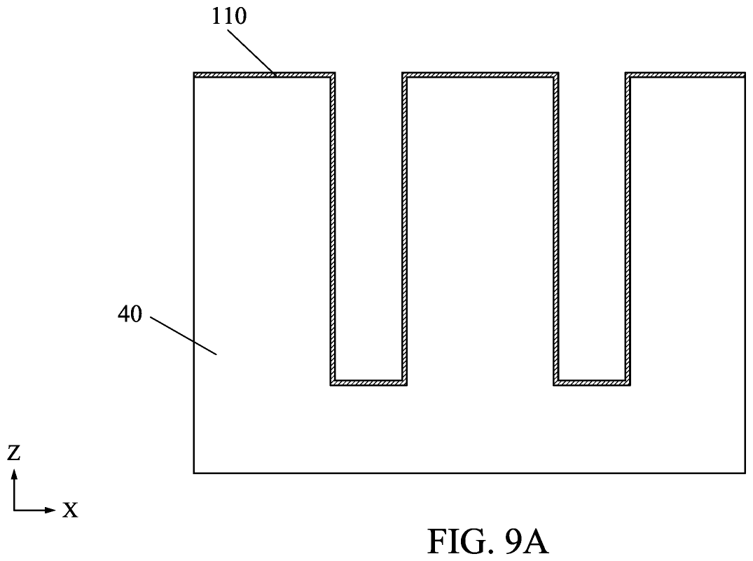

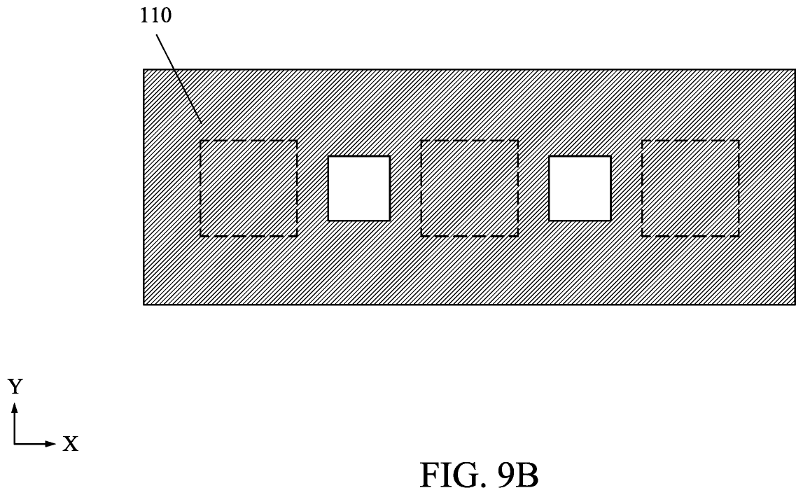

Then, as shown in FIGS. 9A and 9B, a first conductive layer 110 for a first data storage electrode is conformally formed in the first and second trenches 42 and 44 and on the upper surface of the second ILD layer 40. In some embodiments, the first conductive layer 110 includes one or more layers of Cu, Al, W, Co, Ti or Ta or an alloy thereof. In certain embodiments, one or more layers of Ti, TiN, Ta or TaN are used. In some embodiments, the first conductive layer 110 is formed by chemical vapor deposition (CVD), physical vapor deposition (PVD) including sputtering or atomic layer deposition (ALD). In some embodiments, the thickness of the first conductive layer 110 is in a range from about 1 nm to about 10 nm and is in a range from about 2 nm to about 5 nm in other embodiments, depending on the design and/or process requirements.

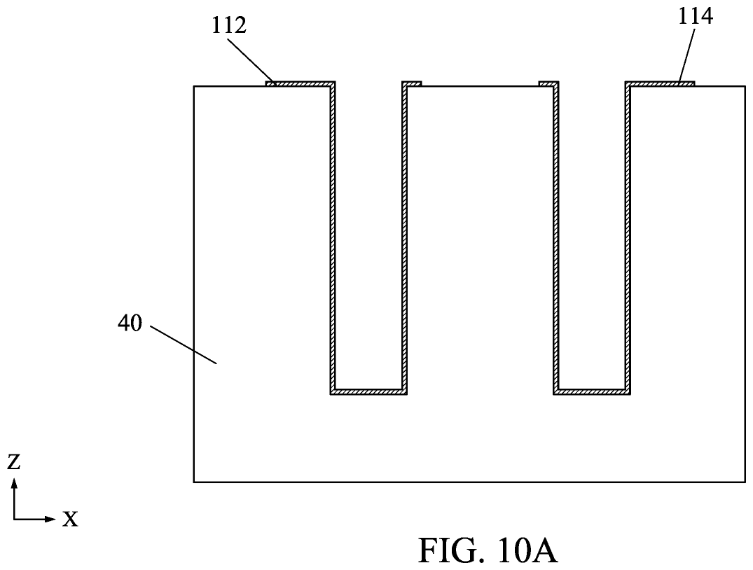

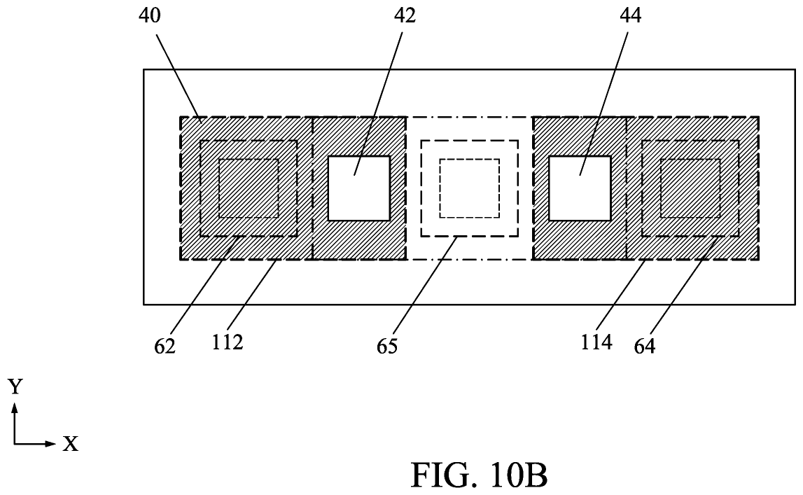

Next, as shown in FIGS. 10A and 10B, the first conductive layer 110 is patterned into a first data storage electrode 112 for a first MIM capacitor 102, and a first date storage electrode 114 for a second MIM capacitor 104, by using one or more lithography and etching operations. As shown in FIG. 10B, the first data storage electrodes extend over and partially or fully overlap the areas where the first and second via electrodes are to be formed (small square inside square showing the lower wiring patterns 62, 64 and 65), and do not overlap the area where the third via electrode is to be formed.

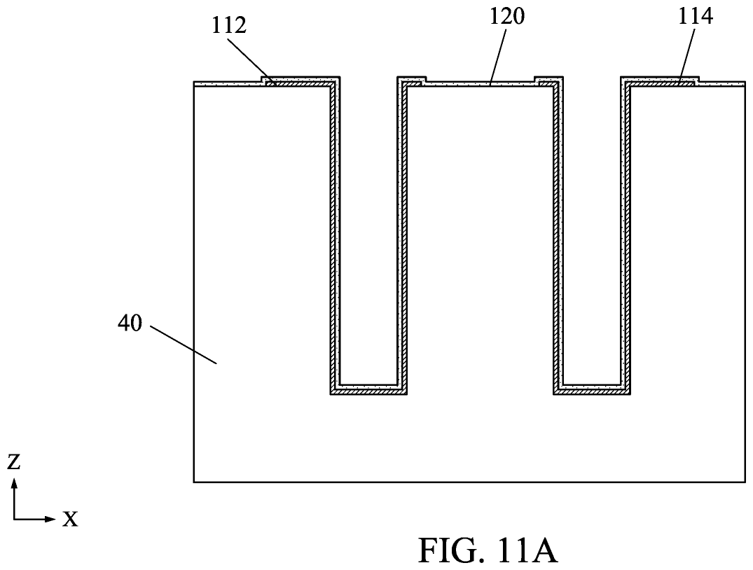

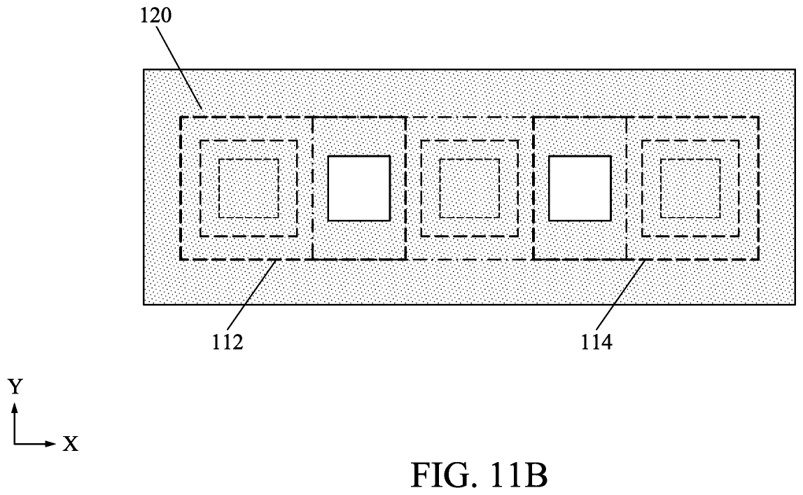

Then, as shown in FIGS. 11A and 11B, a first insulating layer 120 is formed over the first data storage electrodes 112 and 114 and the second ILD layer 40. In some embodiments, the first insulating layer 120 includes one or more high-k dielectric layers having a dielectric constant greater than that of SiO₂. In some embodiments, the first insulating layer 120 includes one or more layers of a metal oxide or a silicate of Hf, Al, Zr, combinations thereof, and multi-layers thereof. In certain embodiments, hafnium oxide is used. Other suitable materials include La, Mg, Ba, Ti, Pb, Zr, in the form of metal oxides, metal alloy oxides, and combinations thereof. Exemplary materials include MgOₓ, BaTiₓO_{y}, BaSrₓTi_{y}O_{z}, PbTiₓO_{y}, PbZrₓTi_{y}O_{z}, SiCN, SiON, SiN, Al₂O₃, La₂O₃, Ta₂O₃, Y₂O₃, HfO₂, ZrO₂, HfSiON, YGeₓO_{y}, YSiₓO_{y} and LaAlO₃, and the like. In some embodiments, the first insulating layer 120 has a thickness in a range from about 1 nm to about 10 nm, and in a range from about 2 nm to about 5 nm in other embodiments, depending on design and/or process requirements. The first insulating layer 120 is formed by CVD or ALD.

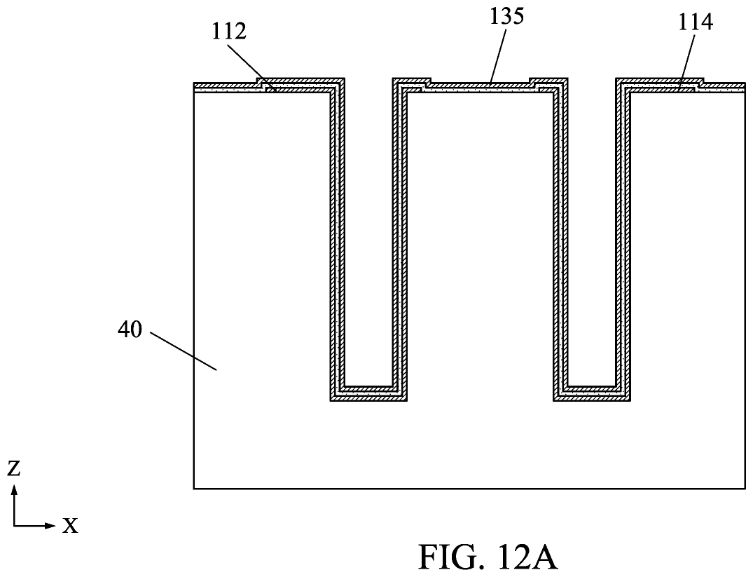

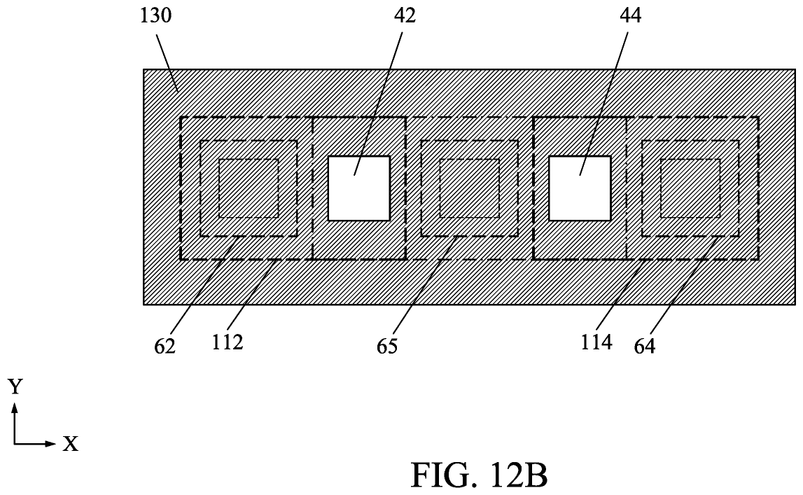

Next, as shown in FIGS. 12A and 12B, a second conductive layer 130 for a first plate electrode is conformally formed in the first and second trenches 42 and 44 and over the first insulating layer 120. In some embodiments, the configuration of the second conductive layer 130 is the same as the configuration of the first conductive layer 110.

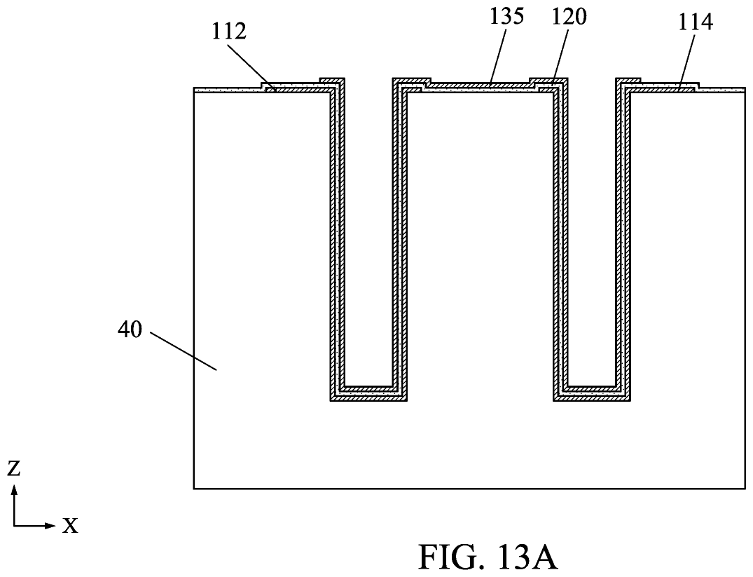

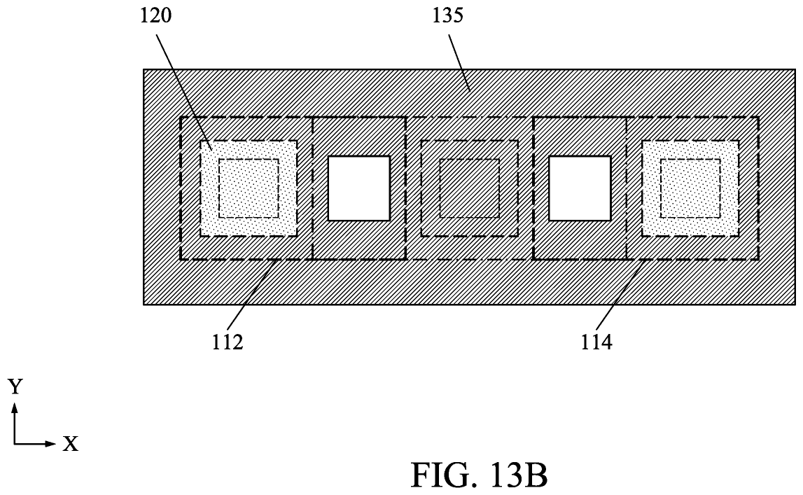

Then, as shown in FIGS. 13A and 13B, the second conductive layer 130 is patterned into a first plate electrode 135 for the first and second MIM capacitors 102 and 104, by using one or more lithography and etching operations. As shown in FIG. 13B, the first plate electrode extends over and partially or fully overlaps the area where the third via electrode is to be formed and has openings over the areas where the first and second via electrodes are to be formed. In some embodiments, the openings are greater than the size of the lower wiring patterns in plan view.

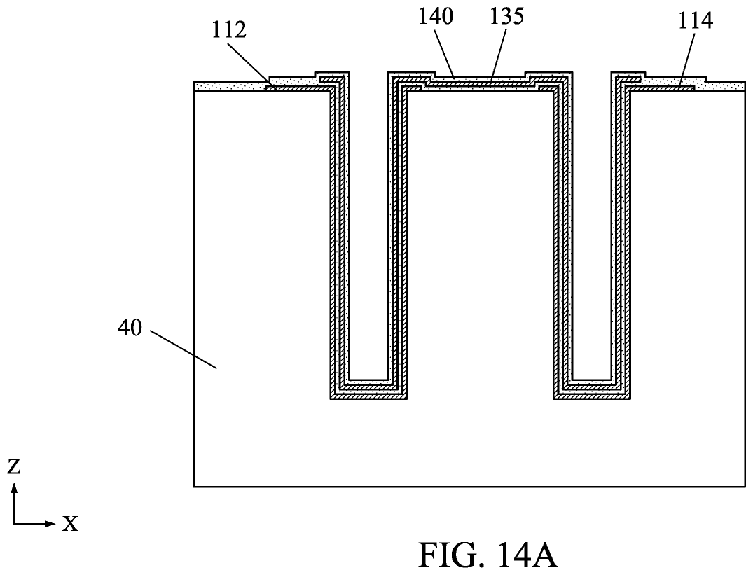

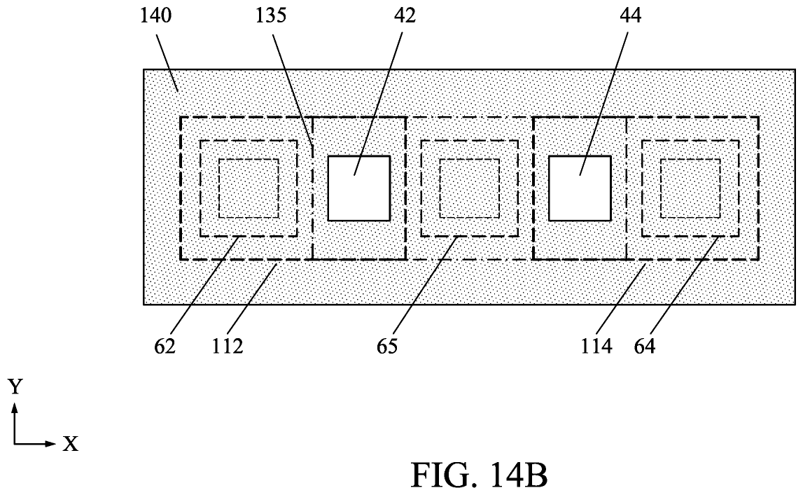

Then, as shown in FIGS. 14A and 14B, a second insulating layer 140 is formed over the first plate electrode 135. In some embodiments, the configuration of the second insulating layer 140 is the same as the configuration of the first insulating layer 120.

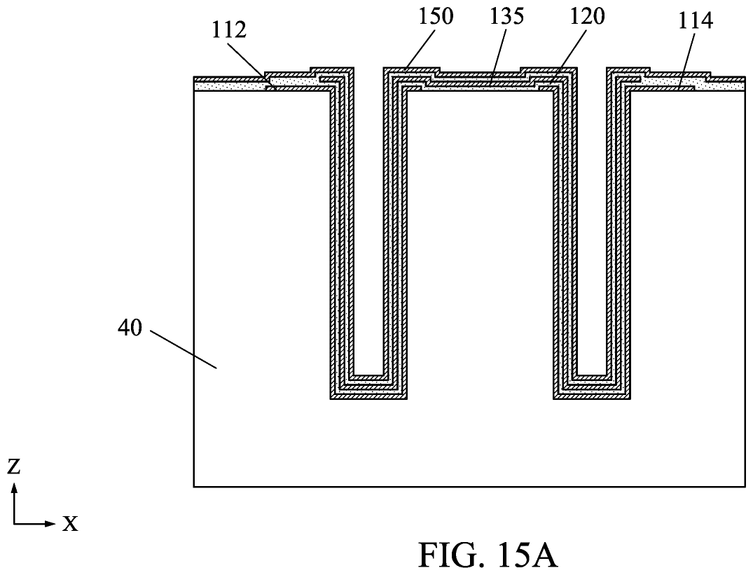

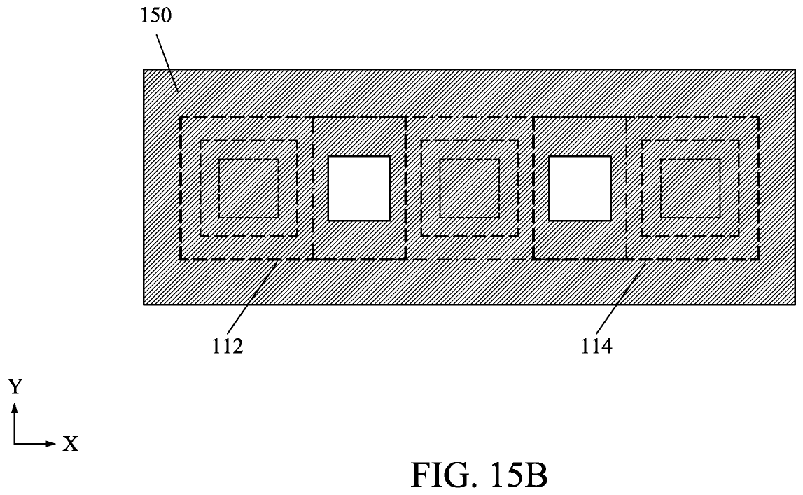

Further, as shown in FIGS. 15A and 15B, a third conductive layer 150 for second data storage electrodes is conformally formed in the first and second trenches 42 and 44 and over the second insulating layer 140. In some embodiments, the configuration of the third conductive layer 150 is the same as the configuration of the first conductive layer 110.

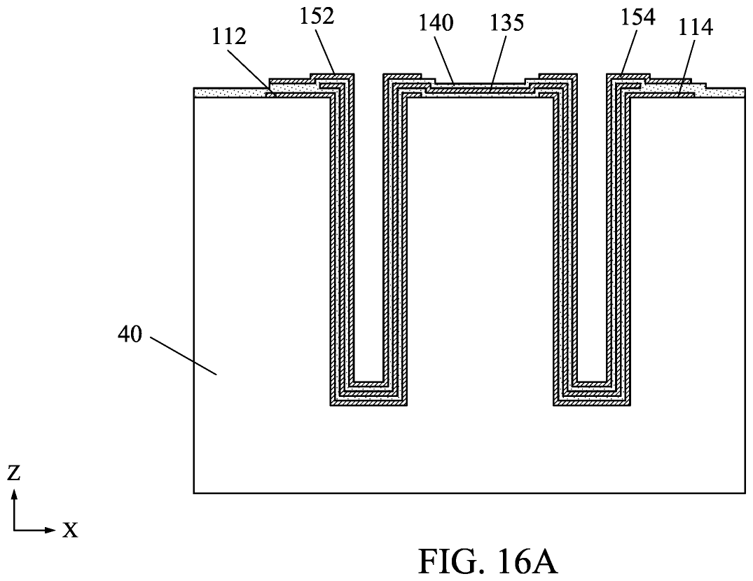

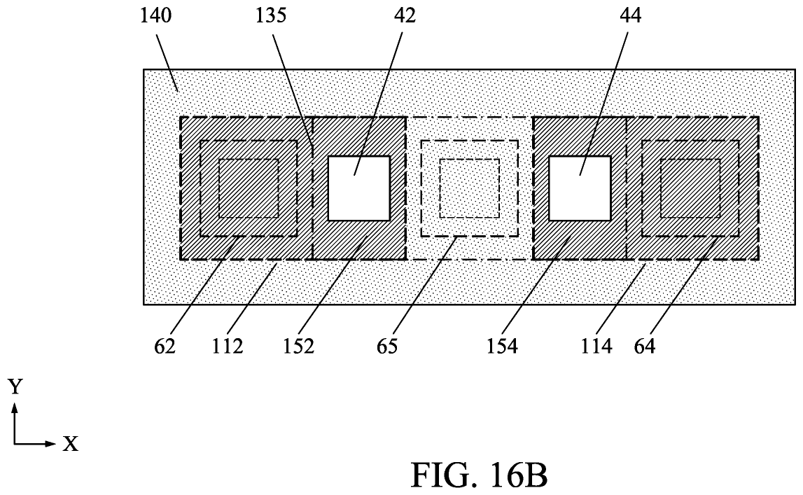

Subsequently, similar to FIGS. 10A and 10B, the third conductive layer 150 is patterned into a second data storage electrode 152 for the first MIM capacitor 102, and a second date storage electrode 154 for the second MIM capacitor 104, by using one or more lithography and etching operations, as shown in FIGS. 16A and 16B. In some embodiments, in the lithography operation, the same photo mask used to form the first data storage electrodes 112 and 114 is used.

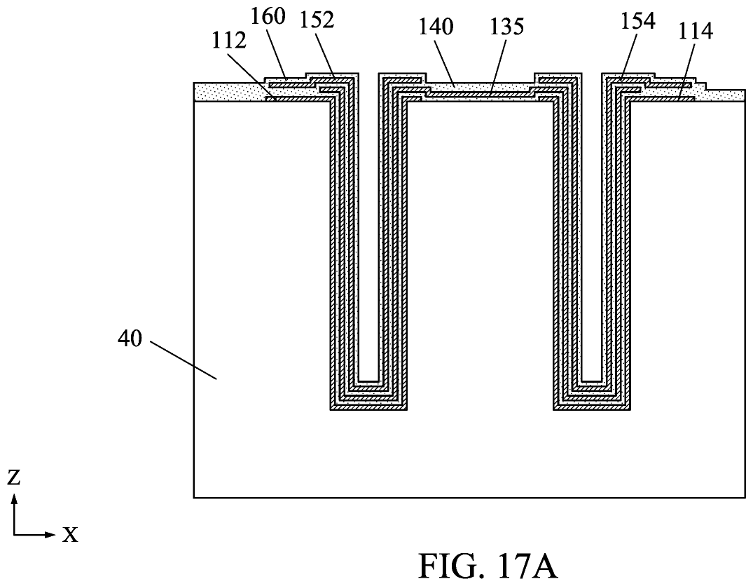

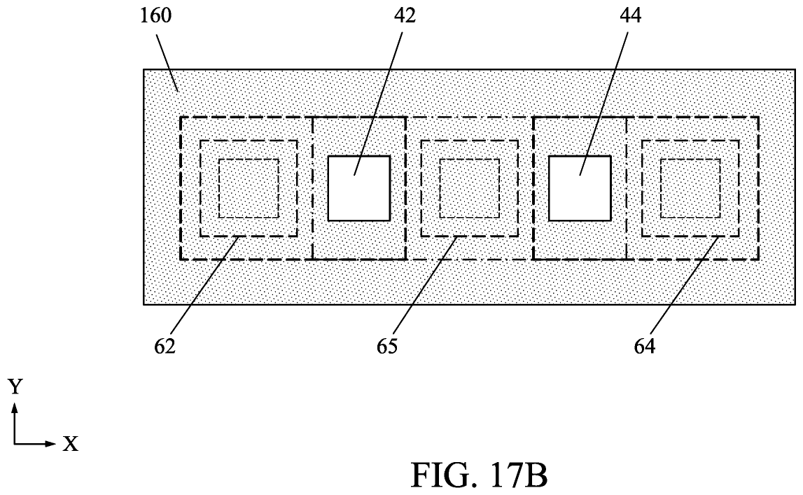

Next, as shown in FIGS. 17A and 17B, a third insulating layer 160 is formed over the second plate electrodes 152 and 154. In some embodiments, the configuration of the third insulating layer 160 is the same as the configuration of the first and second insulating layers 120 and 140.

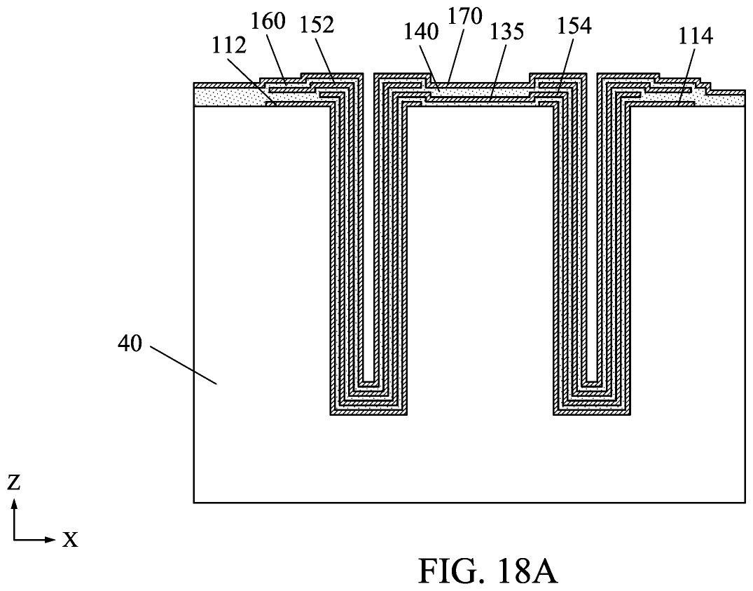

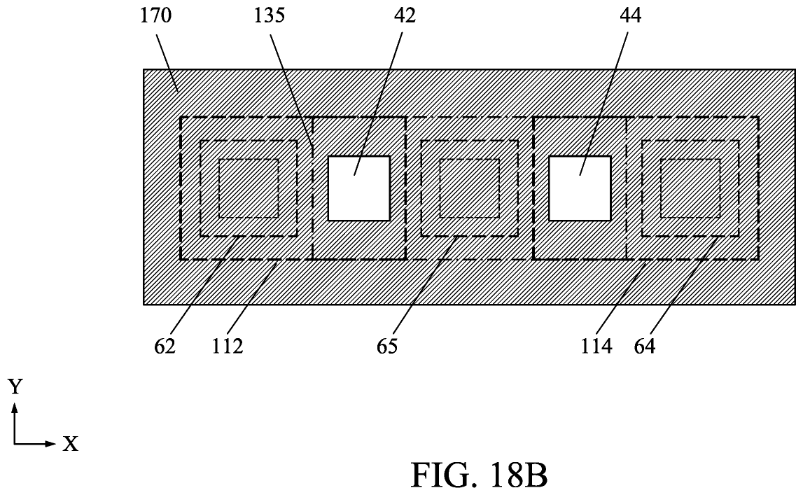

Further, as shown in FIGS. 18A and 18B, a fourth conductive layer 170 for a second plate electrode is conformally formed in the first and second trenches 42 and 44 and over the third insulating layer 160. In some embodiments, the configuration of the fourth conductive layer 170 is the same as the configuration of the first, second and third conductive layers.

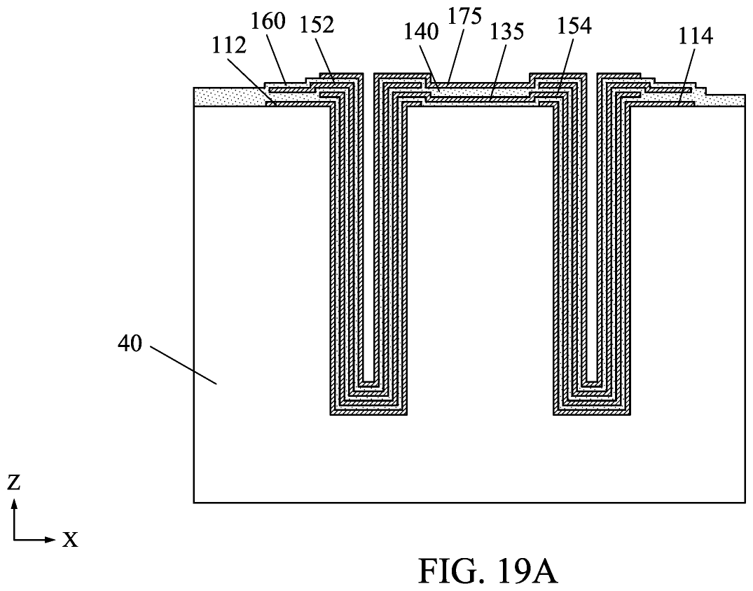

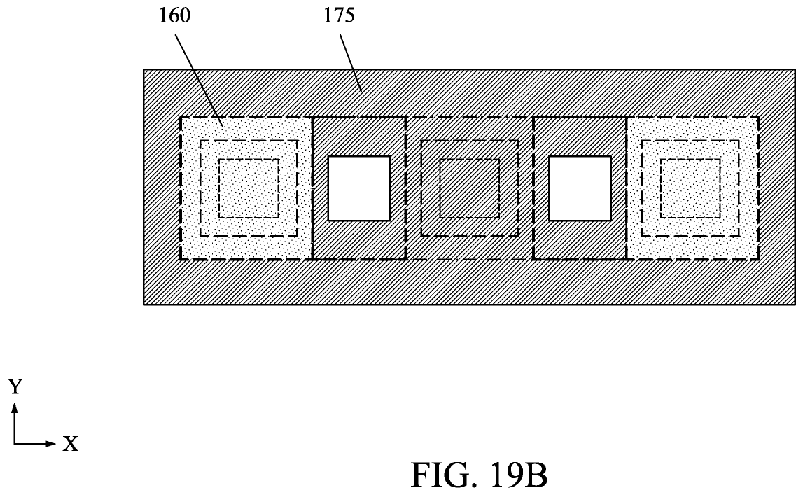

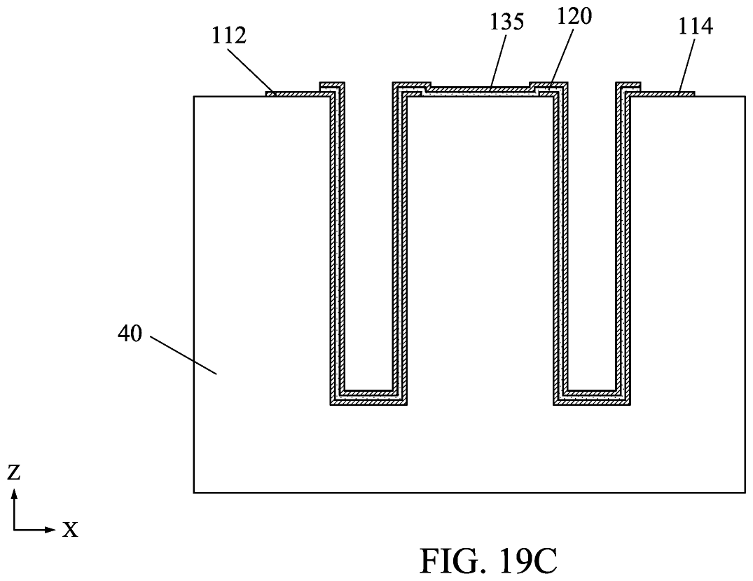

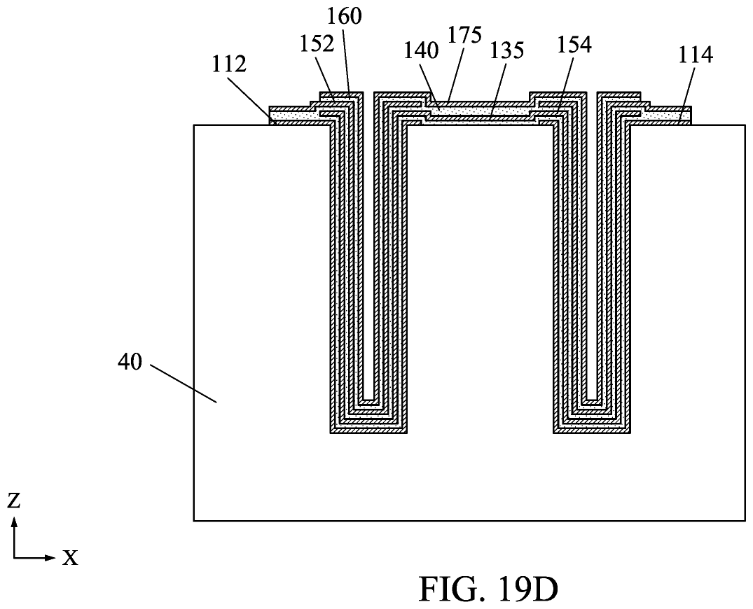

Next, similar to FIGS. 13A and 13B, the fourth conductive layer 170 is patterned into a second plate electrode 175 for the first and second MIM capacitors 102 and 104, by using one or more lithography and etching operations, as shown in FIGS. 19A and 19B. In some embodiments, in the lithography operation, the same photo mask used to form the first plate electrode 135 is used.

Subsequently, further CMOS processes are performed to form various features such as additional interlayer dielectric layers, contacts/vias, interconnect metal layers, and passivation layers, etc.

In some embodiments, forming and patterning a conductive layer and forming an insulating layer are further repeated to obtain MIM capacitors with the desired number of layers.

In some embodiments, part of one or more insulating layers, which is not sandwiched by the electrodes is removed. In some embodiments, after the first plate electrode 135 is formed in FIG. 13A, after the second data storage electrodes are formed in FIG. 16A and/or after the second plate electrode is formed in FIG. 19A, the insulating layers 120, 140 and/or 160 are etched by using the electrode as the etching mask. FIG. 19C shows the structure after part of the first insulating layer 120 not covered by the first plate electrode 135 is etched. FIG. 19D shows a structure when all the insulating layers 120, 140 and/or 160 are subjected to the etching. In this case, there is no insulating layer 108 in the logic circuit region.

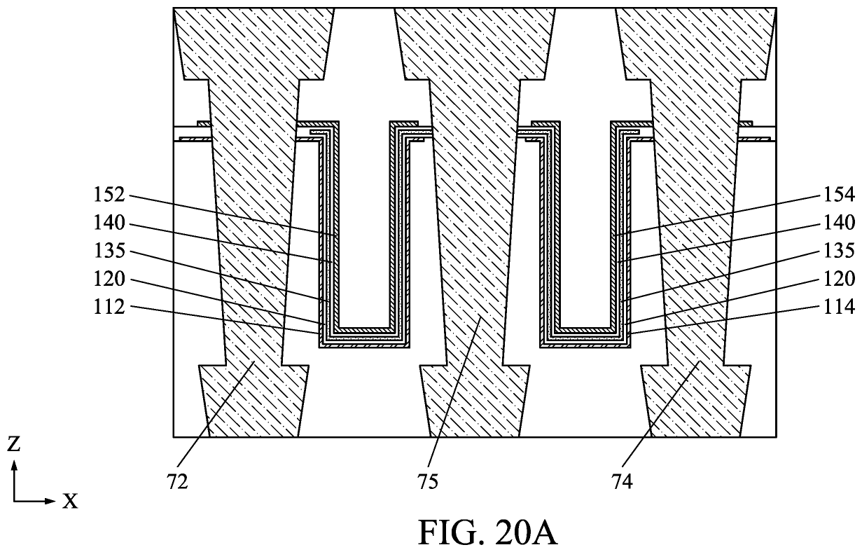

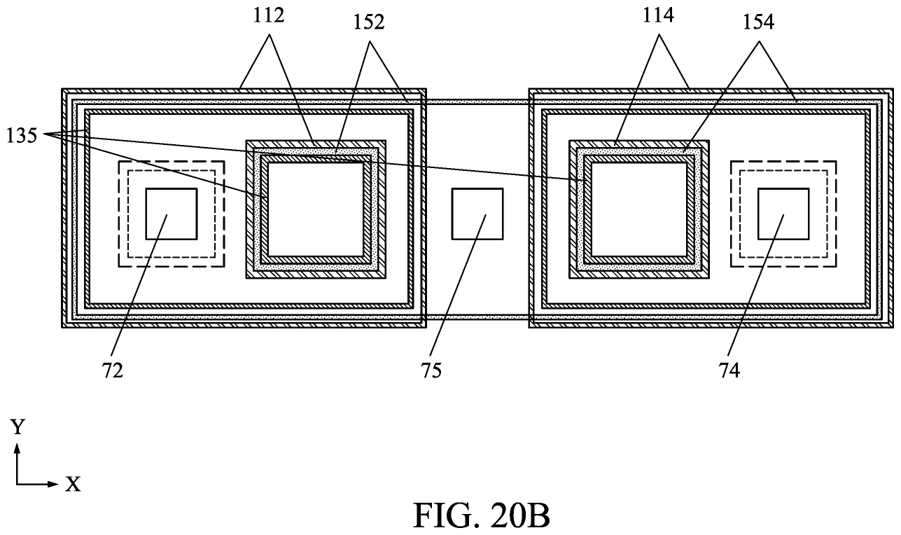

FIGS. 20A and 20B show a semiconductor device including a DRAM cell in accordance with embodiments of the present disclosure. FIG. 20A is a cross sectional view and FIG. 20B is a plan view. In some embodiments, the first MIM capacitor 102 includes a first data storage electrode 112, a plate electrode 135, a first insulating layer 120 disposed between the first data storage electrode 112 and the plate electrode 135, a second data storage electrode 152 and a second insulating layer 140 disposed between the plate electrode 135 and the second data storage electrode 152, and thus has three conductive layers and two insulating layers. Similarly, the second MIM capacitor 104 also has three conductive layers and two insulating layers and includes a first data storage electrode 114, the plate electrode 135, the first insulating layer 120 disposed between the first data storage electrode 114 and the plate electrode 135, a second data storage electrode 154 and the second insulating layer 140 disposed between the plate electrode 135 and the second data storage electrode 154. The first date storage electrodes 112 and 114 are connected to the first via electrode 72 and 74 respectively, and the plate electrode 135 is connected to the third via electrodes 75. The plate electrode 135 has openings around the first and second via electrodes 72 and 74.

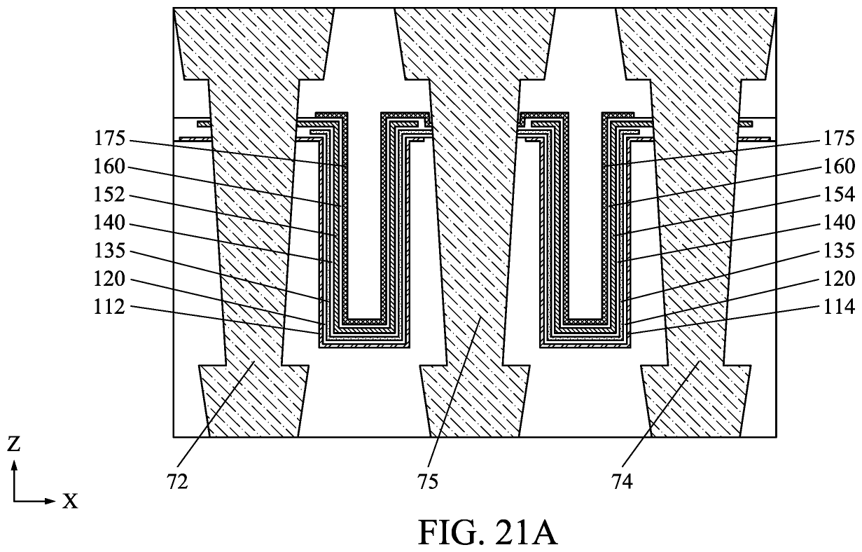

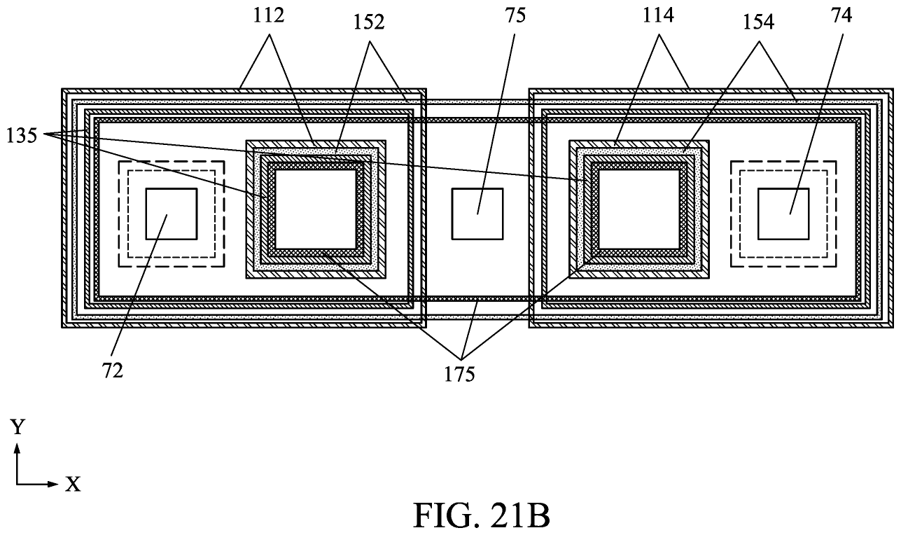

FIGS. 21A and 21B show a semiconductor device including a DRAM cell in accordance with embodiments of the present disclosure. FIG. 21A is a cross sectional view and FIG. 21B is a plan view. In some embodiments, the first MIM capacitor 102 includes a first data storage electrode 112, a first plate electrode 135, a first insulating layer 120 disposed between the first data storage electrode 112 and the first plate electrode 135, a second data storage electrode 152, a second insulating layer 140 disposed between the first plate electrode 135 and the second data storage electrode 152, a second plate electrode 175 and a third insulating layer 160 disposed between the data storage electrode 152 and the second plate electrode 175, and thus has four conductive layers and three insulating layers. Similarly, the second MIM capacitor 104 also has four conductive layers and three insulating layers and includes a first data storage electrode 114, the first plate electrode 135, the first insulating layer 120 disposed between the first data storage electrode 114 and the first plate electrode 135, a second data storage electrode 154, the second insulating layer 140 disposed between the first plate electrode 135 and the second data storage electrode 154, the second plate electrode 175 and the third insulating layer 160 disposed between the data storage electrode 154 and the second plate electrode 175. The first date storage electrodes 112 and 114 and the second data storage electrodes 152 and 154 are connected to the first via electrode 72 and 74 respectively, and the first and second plate electrodes 135 and 175 are connected to the third via electrode 75. The first and second plate electrodes 135 and 175 have openings around the first and second via electrodes 72 and 74.

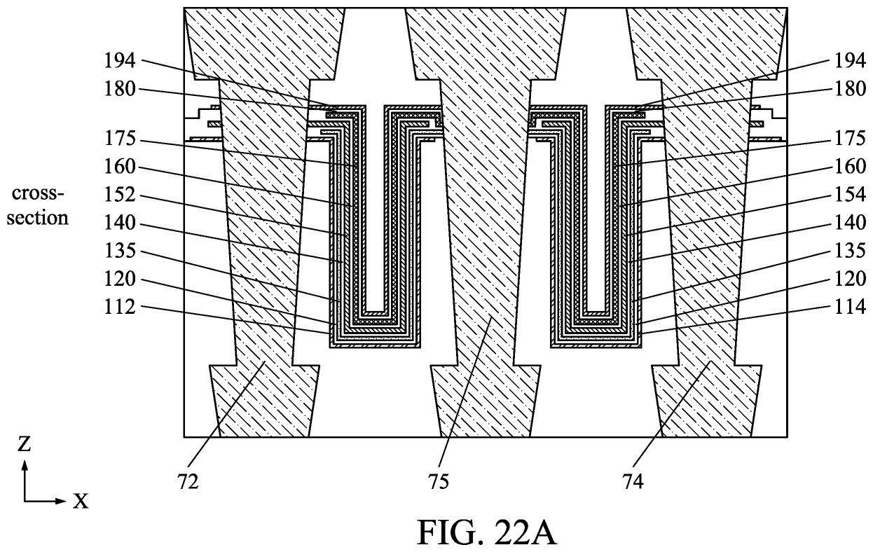

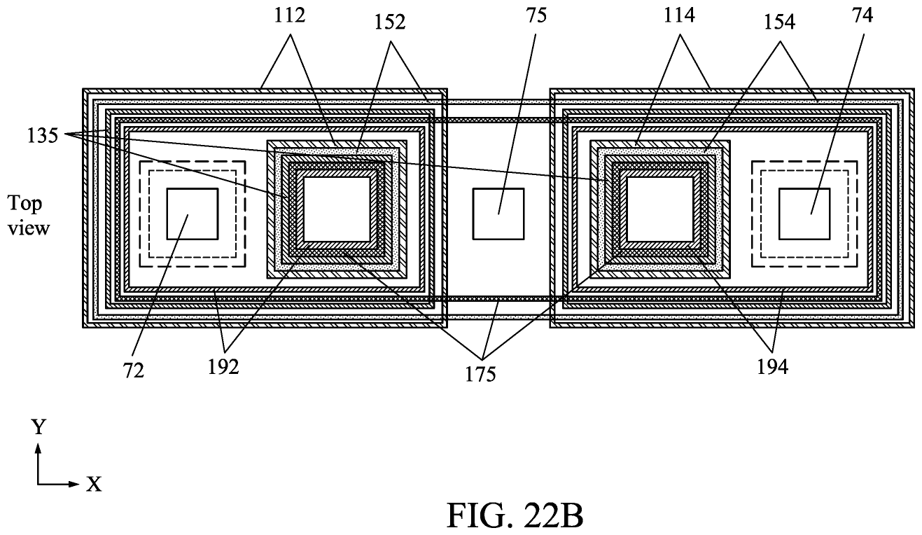

FIGS. 22A and 22B show a semiconductor device including a DRAM cell in accordance with embodiments of the present disclosure. FIG. 22A is a cross sectional view and FIG. 22B is a plan view. In some embodiments, the first MIM capacitor 102 includes a first data storage electrode 112, a first plate electrode 135, a first insulating layer 120 disposed between the first data storage electrode 112 and the first plate electrode 135, a second data storage electrode 152, a second insulating layer 140 disposed between the first plate electrode 135 and the second data storage electrode 152, a second plate electrode 175, a third insulating layer 160 disposed between the data storage electrode 152 and the second plate electrode 175, a third data storage electrode 192 and a fourth insulating layer 180 disposed between the third data storage electrode 192 and the second plate electrode 175, and thus has five conductive layers and four insulating layers. Similarly, the second MIM capacitor 104 also has five conductive layers and four insulating layers, and includes a first data storage electrode 114, the first plate electrode 135, the first insulating layer 120 disposed between the first data storage electrode 114 and the first plate electrode 135, a second data storage electrode 154, the second insulating layer 140 disposed between the first plate electrode 135 and the second data storage electrode 154, the second plate electrode 175, the third insulating layer 160 disposed between the second data storage electrode 154 and the second plate electrode 175, a third data storage electrode 194 and a fourth insulating layer 180 disposed between the third date storage electrode 194 and the second plate electrode 175. The first, second and third date storage electrodes 112 and 114, 152 and 154 and 192 and 194 are connected to the first via electrode 72 and 74 respectively, and the first and second plate electrodes 135 and 175 are connected to the third via electrodes 75. The first and second plate electrodes 135 and 175 have openings around the first and second via electrodes 72 and 74.

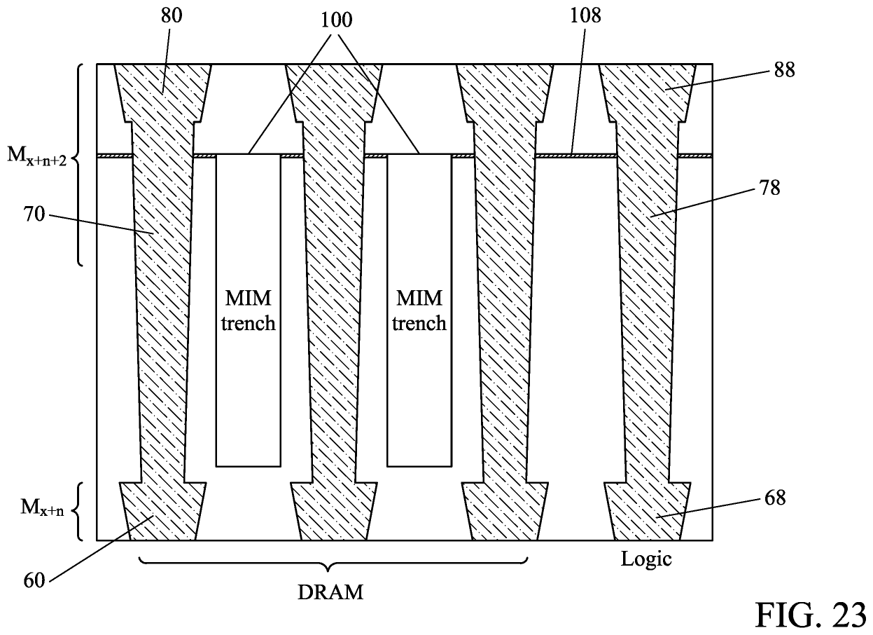

FIG. 23 shows semiconductor devices including a DRAM cell in accordance with embodiments of the present disclosure. In some embodiments, the semiconductor device is a system LSI or system-on-chip (SOC) device including a logic circuit (e.g., a microprocessor) and a DRAM.

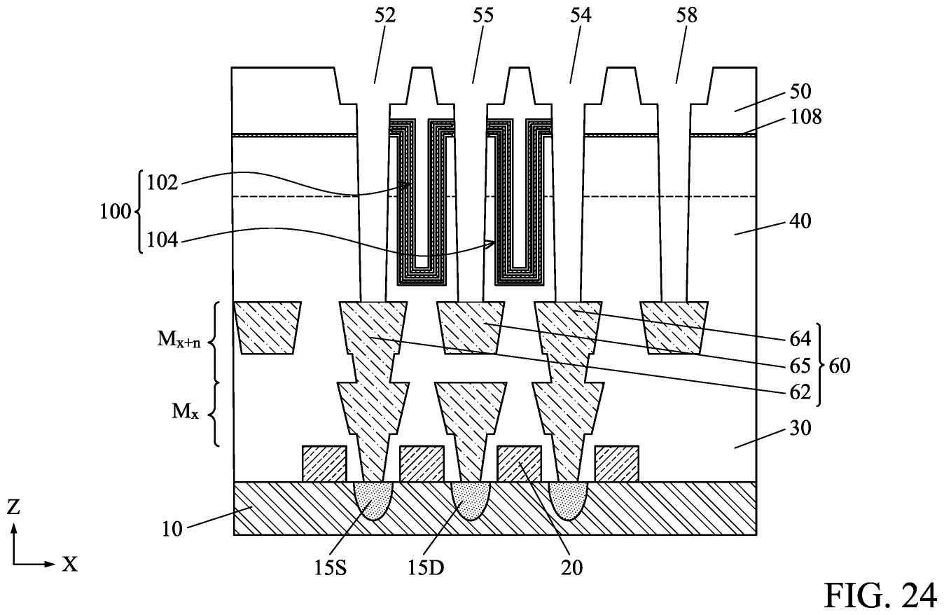

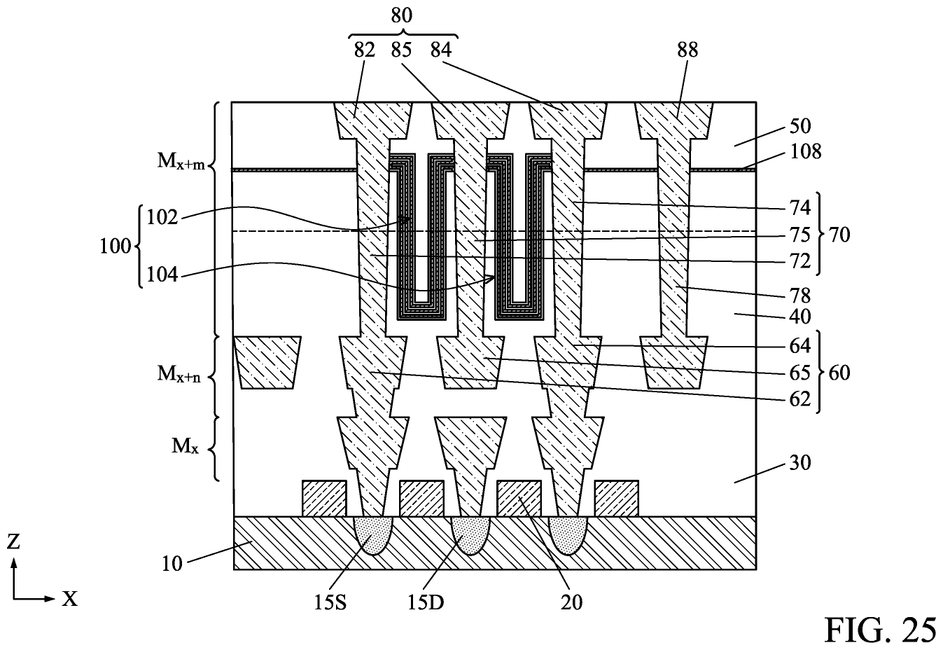

As shown in FIG. 23, the MIM capacitors 100 of the DRAM are disposed between the metal wiring pattern of the Mₓ₊ₙ wiring layer and the metal wiring pattern of the Mₓ₊ₙ₊₁ wiring layer, i.e., between two adjacent metal wiring layers. FIGS. 24 and 25 show cross sectional views of the various stages of a sequential manufacturing operation of a MIM capacitor structure in accordance with embodiments of the present disclosure.

In such a case, via plugs 78 connecting the lower wiring pattern 68 and the upper wiring pattern 88 in the logic circuit and the upper wiring pattern 88 are formed at the same time as the via electrodes 70 and the upper wiring patterns 80 in the DRAM. After the structure shown in FIG. 5 is formed, as shown in FIG. 24, an opening 58 is also formed in the logic circuit region, in some embodiments. Then, as shown in FIG. 25, the opening 58 is also filled with one or more conductive layers to form the via plugs 78 and the upper wiring pattern 88, thereby forming the wiring structure of Mₓ₊ₙ₊ₘ both in the DRAM and logic circuit regions. In some embodiments, the insulating layer 108 is also disposed in the logic circuit and the via plug 78 passes through the insulating layer 108.

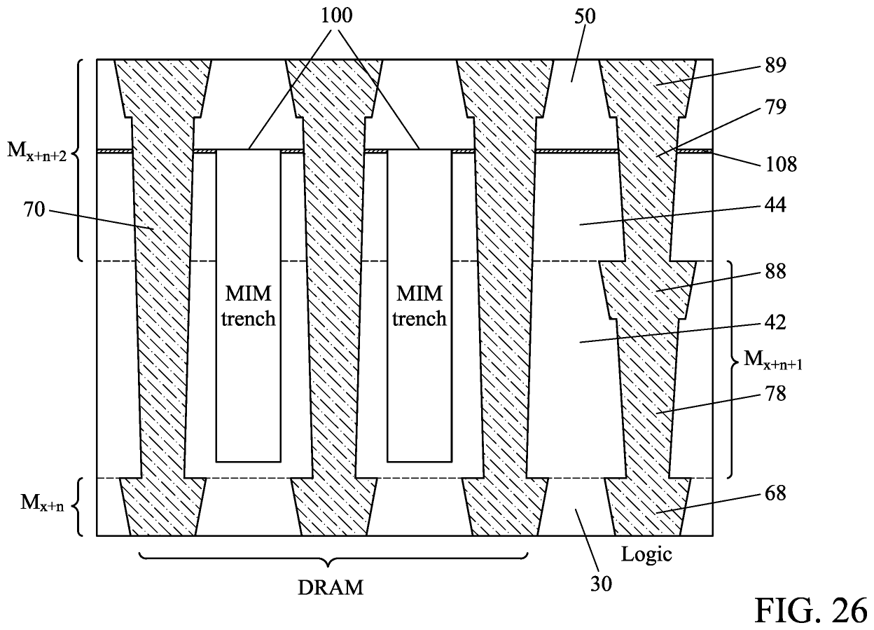

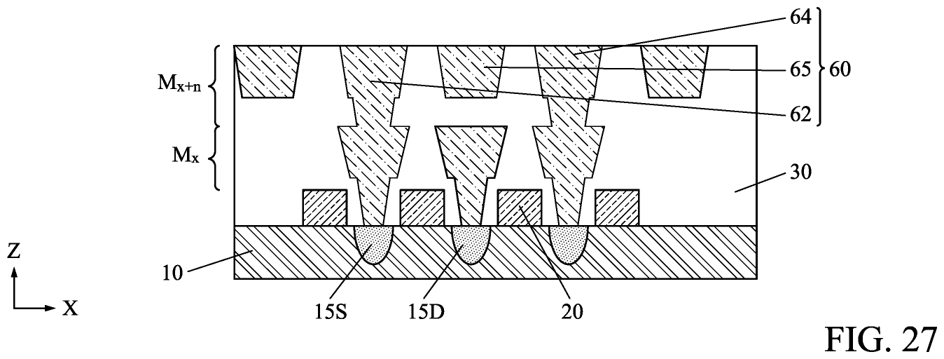

FIG. 26 shows semiconductor devices including a DRAM cell in accordance with embodiments of the present disclosure. FIGS. 27-34 show cross sectional views of the various stages of a sequential manufacturing operation of a MIM capacitor structure in accordance with embodiments of the present disclosure. Similar to FIG. 23, the semiconductor device is a system LSI or system-on-chip (SOC) device including a logic circuit (e.g., a microprocessor) and a DRAM in some embodiments.

As shown in FIG. 26, the MIM capacitors 100 of the DRAM are disposed between the metal wiring pattern of the Mₓ₊ₙ wiring layer and the metal wiring pattern of the Mₓ₊ₙ₊₂ wiring layer.

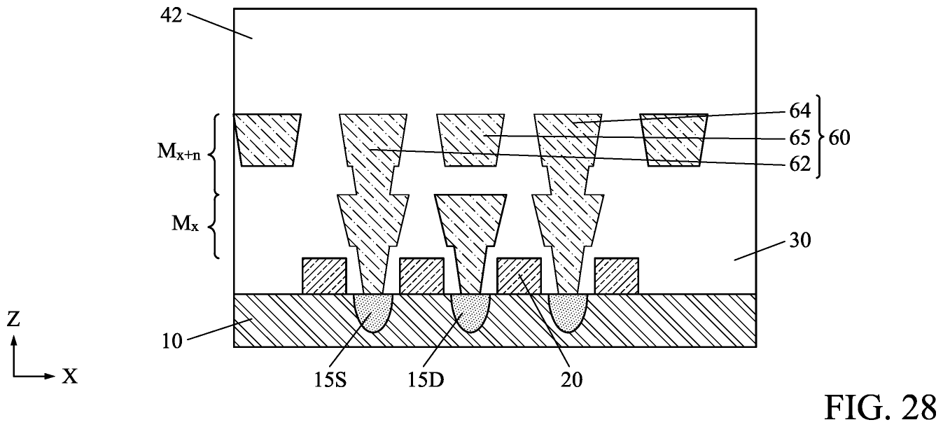

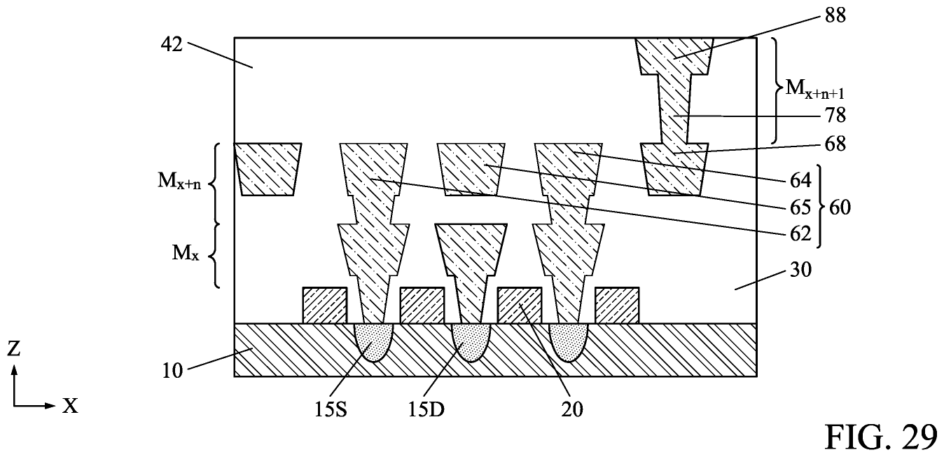

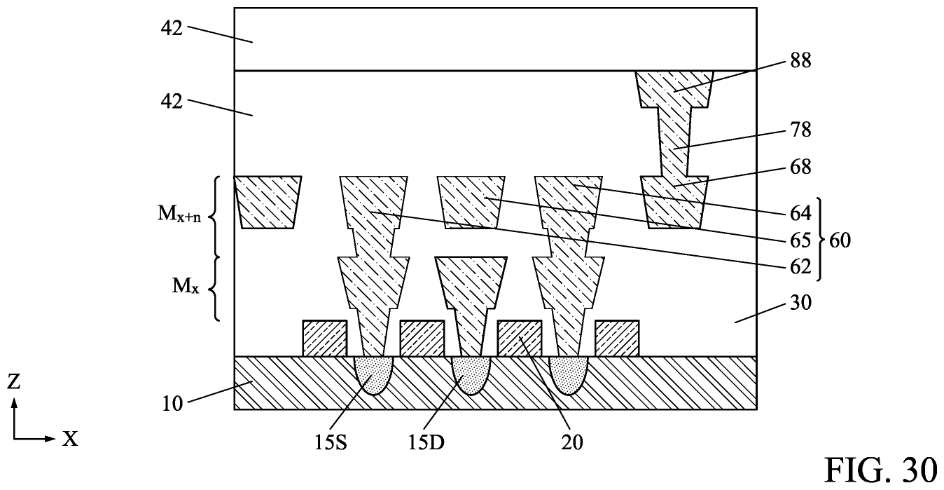

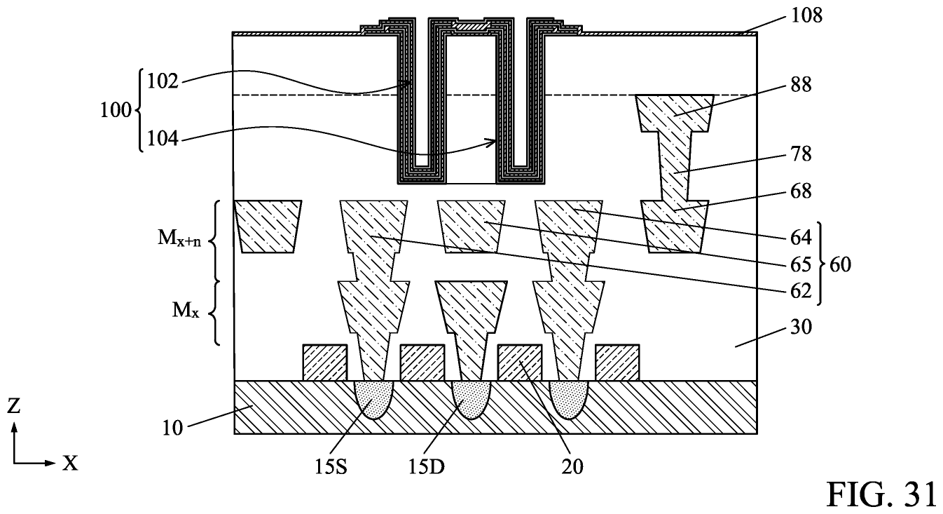

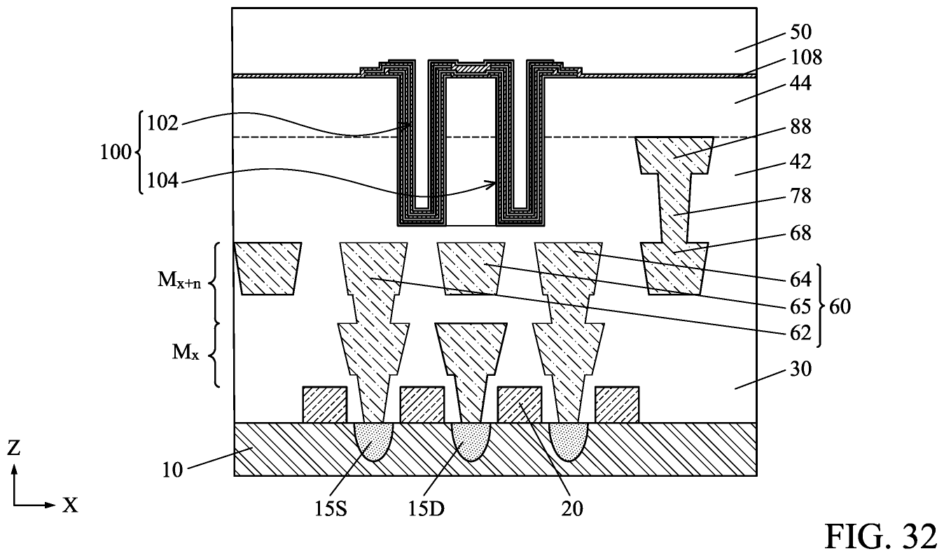

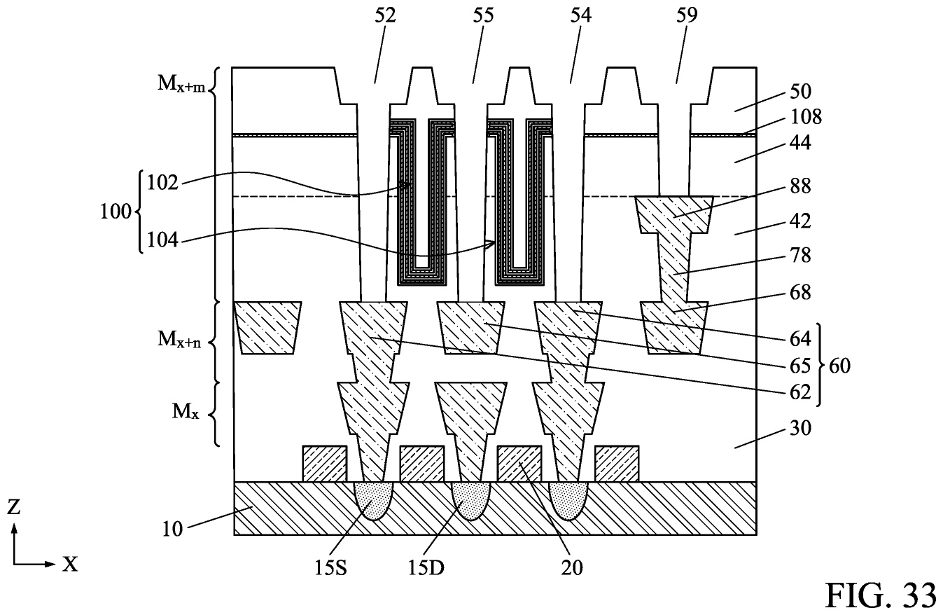

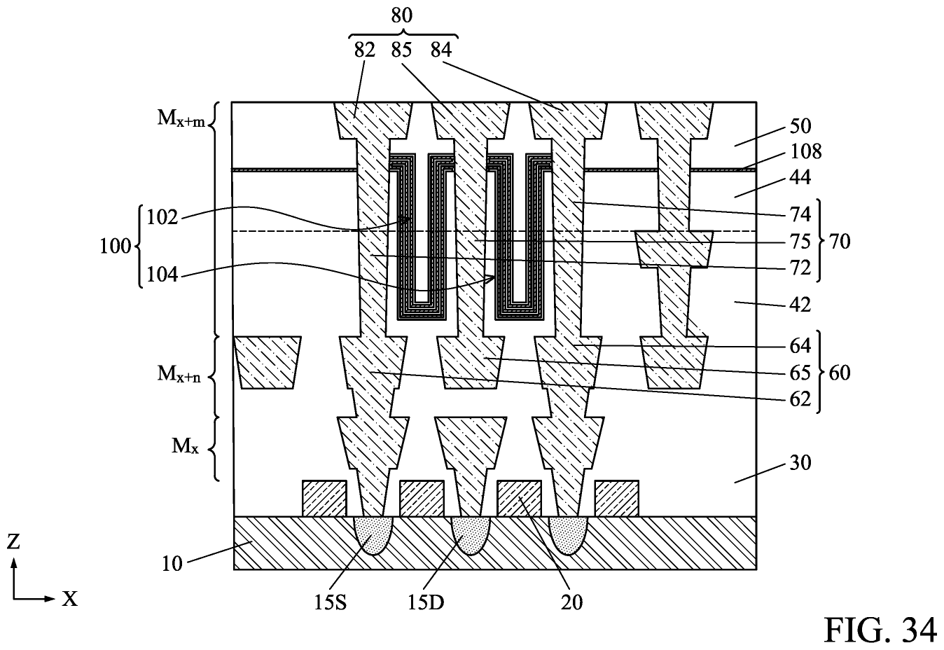

In some embodiments, after the structure shown in FIG. 27, which is consistent with FIG. 2, is formed, an ILD layer 42 is formed as shown in FIG. 28. Then, the wiring structures including the via plug 78 and the wiring pattern 88 of the Mₓ₊ₙ₊₁ wiring layer are formed in the logic circuit as shown in FIG. 29. Then, an ILD layer 44 is formed as shown in FIG. 30. Then, the MIM capacitors 100 are formed as shown in FIG. 31. Further, an ILD layer 50 over the MIM capacitors 100 is formed as shown in FIG. 32. Subsequently, an opening 59 is formed to exposed the wiring pattern 88 as shown in FIG. 33, and then a via plug 79 and a wiring pattern 89 of the Mₓ₊ₙ₊₂ wiring layer in the logic circuit are formed as shown in FIG. 34. In some embodiments, the via plug 79 and the wiring pattern 89 of the Mₓ₊ₙ₊₂ wiring layer in the logic circuit and the via electrodes 70 and the upper wiring patterns 80 in the DRAM are formed at the same time. In other embodiments, before or after the via plug 79 and the wiring pattern 89 of the Mₓ₊ₙ₊₂ wiring layer in the logic circuit are formed, the via electrodes 70 and the upper wiring patterns 80 in the DRAM are formed.

In other embodiments, the MIM capacitors 100 of the DRAM are disposed between the metal wiring pattern of the Mₓ₊ₙ wiring layer and the metal wiring pattern of the Mₓ₊ₙ₊ₘ wiring layer, where m is 3, 4 or 5.

Although the foregoing embodiments are mainly directed to a DRAM structure, the MIM capacitors of the present disclosure can be used as any type of capacitor for a semiconductor device.

In the embodiments of the present disclosure, the MIM capacitors are formed in the ILD layer above the switching transistors of a DRAM structure. With the structure and manufacturing operations as set forth above, it is possible to obtain MIM capacitors with a large and flexible capacitance range having the same MIM height and the same pitch as that of the transistors. It is also possible to easily increase a capacitance of the MIM capacitor by increasing the number of stacked layers of the MIM capacitor. Further, since the MIM capacitors are formed between two wiring patterns, it is possible to reduce an aspect ratio of the trench (in particular the depth of the trench) in which the MIM capacitor is formed.

It will be understood that not all advantages have been necessarily discussed herein, no particular advantage is required for all embodiments or examples, and other embodiments or examples may offer different advantages.

In accordance with an aspect of the present disclosure, a semiconductor device includes a metal-insulator-metal (MIM) capacitor. The MIM capacitor includes: electrodes including one or more first electrodes and one or more second electrodes; and one or more insulating layers disposed between adjacent electrodes. The MIM capacitor is disposed in an interlayer dielectric (ILD) layer disposed over a substrate. The one or more first electrodes are connected to a side wall of a first via electrode disposed in the ILD layer, and the one or more second electrodes are connected to a side wall of a second via electrode disposed in the ILD layer. In one or more of the foregoing or following embodiments, the one or more insulating layers include a high-k dielectric material. In one or more of the foregoing or following embodiments, the MIM capacitor is disposed between wiring patterns at an n-th wiring layer and wiring patterns at an (n+1)-th wiring layer, where n is a natural number. In one or more of the foregoing or following embodiments, the first via electrode connects a first wiring pattern of the wiring patterns at the n-th wiring layer and a first wiring pattern of the wiring patterns at the (n+1)-th wiring layer, and the second via electrode connects a second wiring pattern of the wiring patterns at the n-th wiring layer and a second wiring pattern of the wiring patterns at the (n+1)-th wiring layer. In one or more of the foregoing or following embodiments, the MIM capacitor is disposed between a wiring pattern at an n-th wiring layer and a wiring pattern at an (n+2)-th wiring layer, where n is a natural number. In one or more of the foregoing or following embodiments, the first via electrode directly connects a first wiring pattern of the wiring patterns at the n-th wiring layer and a first wiring pattern of the wiring patterns at the (n+2)-th wiring layer, and the second via electrode directly connects a second wiring pattern of the wiring patterns at the n-th wiring layer and a second wiring pattern of the wiring patterns at the (n+2)-th wiring layer. In one or more of the foregoing or following embodiments, the MIM capacitor includes one first electrode and one second electrode, and one insulating layer. In one or more of the foregoing or following embodiments, the MIM capacitor includes two first electrodes and two second electrodes, and three insulating layers. In one or more of the foregoing or following embodiments, the MIM capacitor includes three first electrodes and two second electrodes, and four insulating layers.

In accordance with another aspect of the present disclosure, a semiconductor device includes: a first transistor and a second transistor which are disposed over a substrate, a plurality of wiring layers disposed over the substrate, a first metal-insulator-metal (MIM) capacitor, and a second MIM capacitor. Each of the first and second MIM capacitors includes: electrodes including one or more first electrodes and one or more second electrodes; and one or more insulating layers disposed between adjacent electrodes. The one or more first electrodes of the first MIM capacitor are connected to a side wall of a first via electrode that is disposed in one or more of the plurality of wiring layers and electrically coupled to a source of the first transistor. The one or more first electrodes of the second MIM capacitor are connected to a side wall of a second via electrode that is disposed in the one or more of the plurality of wiring layers and electrically coupled to a source of the second transistor, and the one or more second electrodes of the first and second MIM capacitors are commonly connected to a side wall of a third via electrode disposed in the one or more of the plurality of wiring layers. In one or more of the foregoing or following embodiments, the third via electrode is electrically coupled to a fixed potential. In one or more of the foregoing or following embodiments, the one or more first electrodes of the first MIM capacitor fully surround the side wall of the first via electrode, and the one or more first electrodes of the second MIM capacitor fully surround the side wall of the second via electrode. In one or more of the foregoing or following embodiments, the one or more second electrodes fully surround the side wall of the third via electrode. In one or more of the foregoing or following embodiments, the first and second MIM capacitors are disposed between wiring patterns at an n-th wiring layer of the plurality of wiring layers and wiring patterns at an (n+m)-th wiring layer of the plurality of wiring layers, where n is a natural number and m is 1, 2 or 3. In one or more of the foregoing or following embodiments, no wiring pattern at the n-th wiring layer is connected to any of the electrodes at a bottom of each of the first and second MIM capacitors. In one or more of the foregoing or following embodiments, each of the first, second and third via electrodes has a single columnar shape.

In accordance with another aspect of the present disclosure, a semiconductor device includes a logic circuit, a dynamic random access memory (DRAM); and a plurality of wiring layers disposed over the substrate. The DRAM includes a switching transistor disposed over a substrate; and a metal-insulator-metal (MIM) capacitor. The MIM capacitor is are disposed between wiring patterns at an n-th wiring layer of the plurality of wiring layers and wiring patterns at an (n+m)-th wiring layer of the plurality of wiring layers, where n is a natural number and m is 1, 2 or 3. The MIM capacitor includes: electrodes including one or more data storage electrodes and one or more plate electrodes; and one or more insulating layers disposed between adjacent electrodes. The one or more data storage electrodes are connected to a side wall of a first via electrode, the first via electrode directly connecting a first wiring pattern at the n-th wiring layer of the plurality of wiring layers and a first wiring pattern at the (n+m)-th wiring layer of the plurality of wiring layers, and the one or more plate electrodes are connected to a side wall of a second via electrode, the second via electrode directly connecting a second wiring pattern at the n-th wiring layer of the plurality of wiring layers and a second wiring pattern at the (n+m)-th wiring layer of the plurality of wiring layers. In one or more of the foregoing or following embodiments, the logic circuit includes a via electrode connected to a third wiring pattern at the (n+m)-th wiring layer of the plurality of wiring layers, and the third via electrode passes through an insulating layer made of a same material as the one or more insulating layers. In one or more of the foregoing or following embodiments, m is 2 or 3, and no wiring pattern at (n+m−1)-th wiring layer of the plurality of wiring layers is disposed in a memory cell area of the DRAM. In one or more of the foregoing or following embodiments, the MIM capacitor is disposed in a trench formed in a dielectric layer, and a depth of the trench is 50% to 90% of a vertical distance between the n-th wiring layer and the (n+m)-th wiring layer.

In accordance with another aspect of the present disclosure, in a method of manufacturing a semiconductor device, a lower wiring pattern is formed in a first interlayer dielectric (ILD) layer. A second ILD layer is formed over the lower wiring pattern. A trench is formed in the second ILD layer. A metal-insulator-metal (MIM) structure is formed in the trench and an upper surface of the second ILD layer. The MIM structure includes electrode layers and one or more insulating layers disposed between adjacent electrode layers. A third ILD layer is formed over the MIM structure. An opening is formed in the third ILD layer and the second ILD layer so that the opening passes through one or more of the electrode layers of the MIM capacitor on the upper surface of the second ILD layer and the lower wiring pattern is exposed at a bottom of the opening. A vertical wiring pattern is formed by filling the opening with a conductive material so that the one or more of the electrode layers connect a side face of the vertical wiring pattern. In one or more of the foregoing or following embodiments, the vertical wiring pattern includes a via portion and a pad portion disposed on the via electrode, and the one or more of the electrode layers is in contact with a side face of the via portion. In one or more of the foregoing or following embodiments, when the MIM structure is formed, (i) a blanket layer of a conductive material is formed, (ii) the blanket layer is patterned, and (iii) a blanket layer of an insulating material is formed. In one or more of the foregoing or following embodiments, (i)-(iii) are repeated at least twice. In one or more of the foregoing or following embodiments, a layer of the insulating material is disposed between and in direct contact with the second ILD layer and the third ILD layer. In one or more of the foregoing or following embodiments, the insulating material includes hafnium oxide. In one or more of the foregoing or following embodiments, the conductive material includes TiN or Ti.

In accordance with another aspect of the present disclosure, in a method of manufacturing a semiconductor device, a first lower wiring pattern, a second lower wiring pattern and a third lower wiring pattern are formed in an first interlayer dielectric (ILD) layer. A second ILD layer is formed over the first to third lower wiring patterns. A first trench and a second trench are formed in the second ILD layer. A metal-insulator-metal (MIM) structure is formed in the first and second trenches and an upper surface of the second ILD layer. The MIM structure includes electrode layers and one or more insulating layers disposed between adjacent electrode layers. A third ILD layer is formed over the MIM structure. A first opening is formed above the first lower wiring pattern, a second opening is formed above the second lower wiring pattern and a third opening is formed above the third lower wiring pattern in the third ILD layer and the second ILD layer so that the first and second openings pass through one or more of the electrode layers of the MIM capacitor on the upper surface of the ILD layer and the third opening passes through one or more of the electrode layers of the MIM capacitor on the upper surface of the ILD layer, which are different from the one or more of the electrode layers of the MIM capacitor through which the first and second openings pass. A first vertical wiring pattern, a second vertical wiring pattern and a third vertical wiring pattern are formed by filling the first, second and third openings with a conductive material, respectively, so that the one or more of the electrode layers through which the first and second openings pass connect a side face of the first and second vertical wiring patterns, respectively, and the one or more of the electrode layers through which the third opening passes connects a side face of the third vertical wiring patterns. In one or more of the foregoing or following embodiments, the first trench is formed at an area between the first lower electrode and the second lower electrode in plan view, and the second trench is formed at an area between the second lower electrode and the third lower electrode in plan view. In one or more of the foregoing or following embodiments, a bottom of the first trench is separated from the first lower electrode and the second lower electrode, and a bottom of the trench is separated from the second lower electrode and the third lower electrode. In one or more of the foregoing or following embodiments, each of the first, second and third vertical wiring patterns includes a via portion and a pad portion disposed on the via electrode, and the one or more of the electrode layers through which the first and second openings pass connect a side face of the via portion of the first and second vertical wiring patterns, respectively, and the one or more of the electrode layers through which the third opening passes connects a side face of the via portion of the third vertical wiring pattern. In one or more of the foregoing or following embodiments, the first, second and third lower wiring patterns are disposed at an n-th wiring layers, and the pad electrode is disposed at an (n+m) wiring layers, where n is a natural number and m is 1, 2 or 3. In one or more of the foregoing or following embodiments, when the MIM structure is formed, (i) a blanket layer of a conductive material is formed, (ii) the blanket layer is patterned, and (iii) a blanket layer of an insulating material is formed. In one or more of the foregoing or following embodiments, (i)-(iii) are repeated at least twice. In one or more of the foregoing or following embodiments, a layer of the insulating material is disposed between and in direct contact with the second ILD layer and the third ILD layer.

In accordance with another aspect of the present disclosure, in a method of manufacturing a semiconductor device, a first lower wiring pattern and a second lower wiring pattern are formed in an memory cell area and a third lower wiring pattern is formed in a logic circuit area. The first, second and third lower wiring patterns are formed in an first interlayer dielectric (ILD) layer. A second ILD layer is formed over the first to third lower wiring patterns. A trench is formed in the second ILD layer. A metal-insulator-metal (MIM) structure is formed in the trench and an upper surface of the second ILD layer. The MIM structure includes electrode layers and one or more insulating layers disposed between adjacent electrode layers. A third ILD layer is formed over the MIM structure and the second ILD layer. A first opening above the first lower wiring pattern and a second opening above the second lower wiring pattern are formed in the third ILD layer and the second ILD layer so that the first opening passes through one or more of the electrode layers of the MIM capacitor on the upper surface of the ILD layer and the second opening passes through one or more of the electrode layers of the MIM capacitor on the upper surface of the ILD layer, which are different from the one or more of the electrode layers of the MIM capacitor through which the first opening passes. A first vertical wiring pattern and a second vertical wiring pattern are formed by filling the first and second openings with a conductive material, respectively, so that the one or more of the electrode layers through which the first opening passes connect a side face of the first vertical wiring pattern, and the one or more of the electrode layers through which the second opening passes connects a side face of the second vertical wiring pattern. In one or more of the foregoing or following embodiments, a third opening is formed above the third lower wiring pattern in the third ILD layer and the second ILD layer, and a third vertical wiring pattern is formed by filling the third opening with the conductive material. In one or more of the foregoing or following embodiments, an insulating layer made of a same material as the one or more insulating layers of the MIM structure is formed in the logic circuit area, and the third opening passes through the insulating layer. In one or more of the foregoing or following embodiments, the insulating layer is made of a high-k dielectric material. In one or more of the foregoing or following embodiments, the MIM structure is disposed between a wiring pattern at an n-th wiring layer to which the first, second and third wiring patterns belong and a wiring pattern at an (n+2)-th wiring layer, where n is a natural number, and the first and second openings are formed after a wiring pattern at an (n+1)-th wiring layer in the logic circuit area is formed.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising a metal-insulator-metal (MIM) capacitor, wherein:
the MIM capacitor includes:
electrodes including one or more first electrodes and one or more second electrodes; and
one or more insulating layers disposed between adjacent electrodes,
the MIM capacitor is disposed in an interlayer dielectric (ILD) layer disposed over a substrate,
the one or more first electrodes are connected to a side wall of a first via electrode disposed in the ILD layer, and
the one or more second electrodes are connected to a side wall of a second via electrode disposed in the ILD layer.

2. The semiconductor device of claim 1, wherein the one or more insulating layers include a high-k dielectric material.

3. The semiconductor device of claim 1, wherein the MIM capacitor is disposed between wiring patterns at an n-th wiring layer and wiring patterns at an (n+1)-th wiring layer, where n is a natural number.

4. The semiconductor device of claim 3, wherein:
the first via electrode connects a first wiring pattern of the wiring patterns at the n-th wiring layer and a first wiring pattern of the wiring patterns at the (n+1)-th wiring layer, and
the second via electrode connects a second wiring pattern of the wiring patterns at the n-th wiring layer and a second wiring pattern of the wiring patterns at the (n+1)-th wiring layer.

5. The semiconductor device of claim 1, wherein the MIM capacitor is disposed between a wiring pattern at an n-th wiring layer and a wiring pattern at an (n+2)-th wiring layer, where n is a natural number.

6. The semiconductor device of claim 5, wherein:
the first via electrode directly connects a first wiring pattern of the wiring patterns at the n-th wiring layer and a first wiring pattern of the wiring patterns at the (n+2)-th wiring layer, and
the second via electrode directly connects a second wiring pattern of the wiring patterns at the n-th wiring layer and a second wiring pattern of the wiring patterns at the (n+2)-th wiring layer.

7. The semiconductor device of claim 1, wherein the MIM capacitor includes one first electrode and one second electrode, and one insulating layer.

8. The semiconductor device of claim 1, wherein the MIM capacitor includes two first electrodes and two second electrodes, and three insulating layers.

9. The semiconductor device of claim 1, wherein the MIM capacitor includes three first electrodes and two second electrodes, and four insulating layers.

10. A semiconductor device comprising:
a first transistor and a second transistor which are disposed over a substrate;
a plurality of wiring layers disposed over the substrate;
a first metal-insulator-metal (MIM) capacitor; and
a second MIM capacitor, wherein:
each of the first and second MIM capacitors includes:
electrodes including one or more first electrodes and one or more second electrodes; and
one or more insulating layers disposed between adjacent electrodes,
the one or more first electrodes of the first MIM capacitor are connected to a side wall of a first via electrode that is disposed in one or more of the plurality of wiring layers and electrically coupled to a source of the first transistor,
the one or more first electrodes of the second MIM capacitor are connected to a side wall of a second via electrode that is disposed in the one or more of the plurality of wiring layers and electrically coupled to a source of the second transistor, and
the one or more second electrodes of the first and second MIM capacitors are commonly connected to a side wall of a third via electrode disposed in the one or more of the plurality of wiring layers.

11. The semiconductor device of claim 10, wherein the third via electrode is electrically coupled to a fixed potential.

12. The semiconductor device of claim 10, wherein:
the one or more first electrodes of the first MIM capacitor fully surround the side wall of the first via electrode, and
the one or more first electrodes of the second MIM capacitor fully surround the side wall of the second via electrode.

13. The semiconductor device of claim 12, wherein the one or more second electrodes fully surround the side wall of the third via electrode.

14. The semiconductor device of claim 10, wherein the first and second MIM capacitors are disposed between wiring patterns at an n-th wiring layer of the plurality of wiring layers and wiring patterns at an (n+m)-th wiring layer of the plurality of wiring layers, where n is a natural number and m is 1, 2 or 3.

15. The semiconductor device of claim 14, wherein no wiring pattern at the n-th wiring layer is connected to any of the electrodes at a bottom of each of the first and second MIM capacitors.

16. The semiconductor device of claim 14, wherein each of the first, second and third via electrodes has a single columnar shape.

17. A method of manufacturing a semiconductor device, comprising:
forming a lower wiring pattern in a first interlayer dielectric (ILD) layer;
forming a second ILD layer over the lower wiring pattern;
forming a trench in the second ILD layer;
forming a metal-insulator-metal (MIM) structure in the trench and an upper surface of the second ILD layer, the MIM structure including electrode layers and one or more insulating layers disposed between adjacent electrode layers;
forming a third ILD layer over the MIM structure;
forming an opening in the third ILD layer and the second ILD layer so that the opening passes through one or more of the electrode layers of the MIM capacitor on the upper surface of the second ILD layer and the lower wiring pattern is exposed at a bottom of the opening; and
forming a vertical wiring pattern by filling the opening with a conductive material so that the one or more of the electrode layers connect a side face of the vertical wiring pattern.

18. The method of claim 17, wherein the vertical wiring pattern includes a via portion and a pad portion disposed on the via electrode, and the one or more of the electrode layers is in contact with a side face of the via portion.

19. The method of claim 17, wherein the forming the MIM structure comprises:
(i) forming a blanket layer of a conductive material;
(ii) patterning the blanket layer; and
(iii) forming a blanket layer of an insulating material.

20. The method of claim 19, wherein (i)-(iii) are repeated at least twice.
